(19) United States
(12) Patent Application Publication
(10) Pub. No.: US 2026/0363054 A1
(43) Pub. Date: Nov. 12, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Chia-Ling CHUNG, Hsinchu City (TW); Chih-Hsuan OU YANG, Taoyuan City (TW); Chun-Neng LIN, Hsinchu (TW)

(21) Appl. No.: 19/319,276

(22) Filed: Sep. 4, 2025

Related U.S. Application Data
(60) Provisional application No. 63/803,053, filed on May 9, 2025.

(51) Int. Cl. H10W 20/41; H10D 30/00; H10D 30/01; H10D 30/43; H10D 62/10; H10D 62/13; H10D 84/01; H10D 84/83; H10W 20/00; H10W 20/40; H10W 20/42; H10W 20/43

(52) U.S. Cl. CPC H10W 20/435; H10D 30/014; H10D 30/0191; H10D 30/43; H10D 30/502; H10D 62/121; H10D 62/151; H10D 84/0149; H10D 84/832; H10W 20/081; H10W 20/082; H10W 20/084; H10W 20/42; H10W 20/43; H10W 20/498; H10D 62/102

(57) ABSTRACT

A first etch operation is performed to form a recess for an interconnect structure in an interconnect layer of a semiconductor device over a contact structure and/or a gate structure of an integrated circuit device in a device layer of the semiconductor device. To remove contaminants embedded in the exposed surfaces of the contact structure and/or the gate structure, a second etch operation may be performed prior to formation of the interconnect structure to etch the exposed surfaces of the contact structure and/or the gate structure in the recess. The second etch operation may be performed using a mild etchant, such as ozonated deionized water, to remove a small amount of material from the exposed surfaces of the contact structure and/or the gate structure and to avoid excessive etching of the exposed surfaces of the contact structure and/or the gate structure.

### CROSS-REFERENCE TO RELATED APPLICATION

This Patent Application claims priority to U.S. Provisional Patent Application No. 63/803,053, filed on May 9, 2025, and entitled “SEMICONDUCTOR DEVICE AND METHODS OF FORMATION.” The disclosure of the prior Application is considered part of and is incorporated by reference into this Patent Application.

### BACKGROUND

An interconnect layer (sometimes referred to as a back end region or a back end of line (BEOL) region) is a region of a semiconductor device that includes a plurality of layers of conductive structures that are arranged to carry signals and/or to provide power distribution throughout the semiconductor device. The plurality of layers of conductive structures may include various vertically-arranged layers of interconnect structures (e.g., vias) and layers of metallization structures (e.g., trenches, conductive lines, traces).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are diagrams of a portion of an example semiconductor device described herein.

FIGS. 2A-2E are diagrams of an example implementation of forming a device layer (or a portion thereof) of a semiconductor device described herein.

FIGS. 3A-3G are diagrams of an example implementation of forming an interconnect layer (or a portion thereof) of a semiconductor device described herein.

FIGS. 4A-4D are diagrams of an example implementation of forming an interconnect layer (or a portion thereof) of a semiconductor device described herein.

FIGS. 5A-5D are diagrams of an example implementation of forming an interconnect layer (or a portion thereof) of a semiconductor device described herein.

FIGS. 6A-6C are diagrams of an example implementation of forming an interconnect layer (or a portion thereof) of a semiconductor device described herein.

FIGS. 7A-7F are diagrams of an example implementation of forming an interconnect layer (or a portion thereof) of a semiconductor device described herein.

FIGS. 8A-8F are diagrams of an example implementation of forming an interconnect layer (or a portion thereof) of a semiconductor device described herein.

FIG. 9 is a flowchart of an example process associated with forming a semiconductor device described herein.

FIG. 10 is a flowchart of an example process associated with forming a semiconductor device described herein.

FIGS. 11A and 11B are diagrams of example implementations of a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An interconnect layer of a semiconductor device may be formed above a device layer of the semiconductor device. The device layer may include a substrate layer of the semiconductor device and integrated circuit devices (e.g., transistors, capacitor, diodes, memory cells) in and/or on the semiconductor substrate. A layer of contact structures (referred to as source/drain contacts) may be included between the integrated circuit devices and the interconnect layer, and may electrically connect the integrated circuit devices to a bottom-most layer of conductive structures. The bottom-most layer of conductive structures in the interconnect layer may include source/drain interconnect structures coupled to source/drain regions of the integrated circuit devices and/or gate interconnect structures coupled to gate structures of the integrated circuit devices.

To form an interconnect structure (e.g., a source/drain interconnect structure, a gate interconnect structure) in the bottom-most layer of conductive structures in the interconnect layer, a recess may be formed through one or more dielectric layers to expose the top surface of a contact structure and/or the top surface of a gate structure. The electrically conductive material of the interconnect structure may then be deposited in the recess such that the electrically conductive material fills in the recess.

In some cases, contaminants such as native oxides and/or other impurities may form or may be deposited in a recess for an interconnect structure. These contaminants may increase the contact resistance between the interconnect structure and the underlying contact structure or gate structure, which may reduce the operating performance of the semiconductor device in the form of increased power consumption and/or slower operating speeds. A surface cleaning operation may be performed to remove some of these contaminants before formation of the interconnect structure. However, some types of contaminants are difficult to remove by surface cleaning. For example, impurities such as nitride-based byproducts may embed in the top surface of the underlying contact structure or gate structure, which may result in the nitride-based byproducts being unable to be effectively removed.

In some implementations described herein, a first etch operation is performed to form a recess for an interconnect structure in an interconnect layer of a semiconductor device over a contact structure and/or a gate structure of an integrated circuit device in a device layer of the semiconductor device. Contaminants such as native oxides and/or impurities may become embedded in the exposed surfaces of the contact structure and/or the gate structure in the recess prior to formation of the interconnect structure in the recess. To remove these contaminants, a second etch operation may be performed prior to formation of the interconnect structure to etch the exposed surfaces of the contact structure and/or the gate structure in the recess. The second etch operation may be performed using a mild etchant, such as ozonated deionized water, to remove a small amount of material from the exposed surfaces of the contact structure and/or the gate structure and to avoid excessive etching of the exposed surfaces of the contact structure and/or the gate structure. As a result of the second etch operation, the exposed surfaces of the contact structure and/or the gate structure in the recess may be concave or recessed. The material of the interconnect structure may then be deposited in the recess such that the interface between the interconnect structure and the contact structure and/or the gate structure is substantially free of the contaminants. In this way, a low contact resistance may be achieved at the interface, which may enable the semiconductor device to achieve greater power efficiency and faster operating speeds.

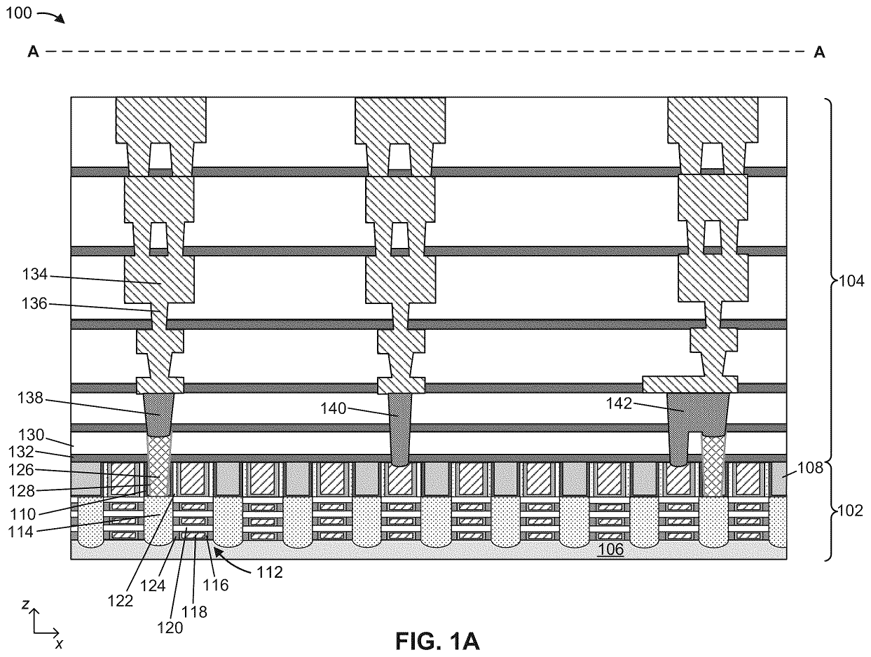

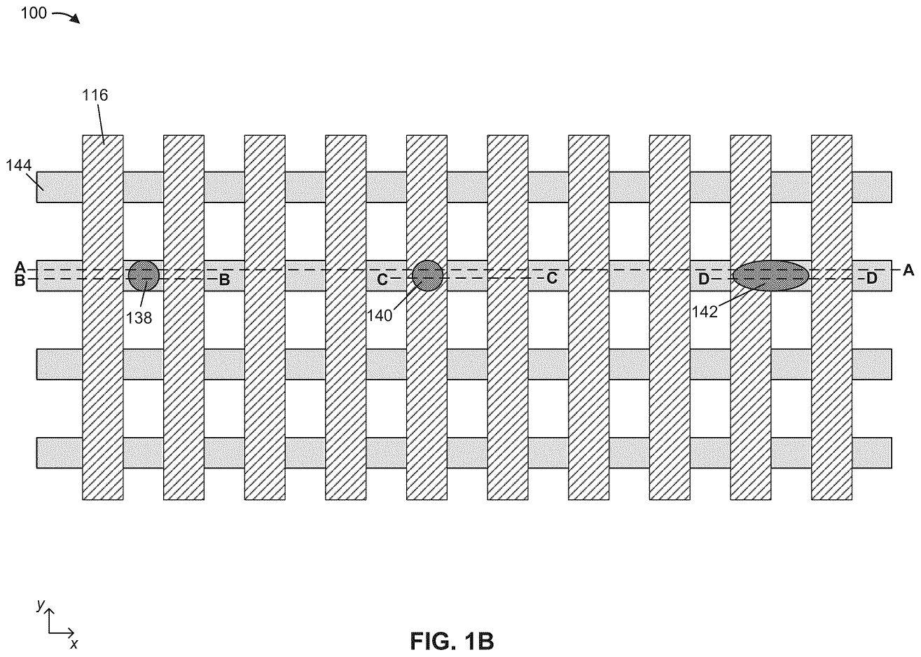

FIGS. 1A and 1B are diagrams of a portion of an example semiconductor device 100 described herein. The semiconductor device 100 may include a system on chip (SoC) device, a logic device such as a central processing unit (CPU) or a graphics processing unit (GPU), a memory device (e.g., a high bandwidth memory (HBM) device), a panel driver device, an integrated circuit (IC) driver, a radio frequency (RF) power amplifier, a display driver IC (DDIC), and/or another type of semiconductor device.

FIG. 1A illustrates a cross-section view of the semiconductor device 100 along the line A-A illustrated in a top view of the semiconductor device 100 in FIG. 1B. As shown in FIG. 1A, the semiconductor device 100 may include a device layer 102 and an interconnect layer 104 above the device layer 102 in a z-direction in the semiconductor device 100. The device layer 102 includes a substrate layer 106. The substrate layer 106 may correspond to a portion of a semiconductor wafer on which the semiconductor device 100 is formed. The substrate layer 106 includes a silicon (Si) substrate, a substrate formed of a material including silicon, a III-V compound semiconductor material substrate such as gallium arsenide (GaAs), a silicon on insulator (SOI) substrate, or another type of semiconductor substrate. The substrate layer 106 may extend in an x-direction and/or in a y-direction in the semiconductor device 100.

A dielectric layer 108 is included over the substrate layer 106. The dielectric layer 108 includes an interlayer dielectric (ILD) layer (e.g., an ILDO layer), an etch stop layer (ESL), and/or another type of dielectric layer. The dielectric layer 108 includes dielectric material(s) that enable various portions of the substrate layer 106 to be selectively etched or protected from etching, and/or may electrically isolate integrated circuit devices 112 in the device layer 102.

The dielectric layer 108 includes an oxide (e.g., a silicon oxide (SiOx) and/or another oxide material), and/or another type of dielectric material. The dielectric layer 108 may extend in the x-direction and/or in a y-direction in the semiconductor device 100.

The dielectric layer 108 may be included on a contact etch stop layer (CESL) 110. The CESL 110 may wrap around the sides and bottoms of the portions of the dielectric layer 108.

The CESL 110 may include a silicon nitride (SiₓN_{y}) material and/or another suitable dielectric material that is different from the material of the dielectric layer 108.

The integrated circuit devices 112 may be included in and/or on the substrate layer 106, and/or in the dielectric layer 108 in the device layer 102 of the semiconductor device 100. The integrated circuit devices 112 include transistors (e.g., planar transistors, fin field effect transistors (finFETs), gate all around (GAA) transistors), pixel sensors, capacitors, resistors, inductors, photodetectors, transceivers, transmitters, receives, optical circuits, and/or other types of semiconductor devices.

An integrated circuit device 112 may include a plurality of source/drain regions 114 that are grown and/or otherwise formed on and/or around portions of the substrate layer 106. “Source/drain region(s)” may refer to a source or a drain, individually or collectively, dependent upon the context. The source/drain regions 114 may be formed by epitaxially growing doped semiconductor regions and/or by another semiconductor process. In some implementations, the source/drain regions 114 are formed in recessed portions in the substrate layer 106. The recessed portions may be formed by strained source/drain (SSD) etching of the substrate layer 106 and/or another type etching operation. In some implementations, the source/drain regions 114 are formed in recesses that are formed in an alternating stack of channel layers and sacrificial layers (e.g., silicon germanium (SiGe) layers).

An integrated circuit device 112 may further include a gate dielectric layer 116 between a gate structure 118 and channel layers 120 of the integrated circuit device 112. The channel layers 120 may extend between the source/drain regions 114 of the integrated circuit device 112, and gate dielectric layer 116 and the gate structure 118 may wrap around two or more sides of the channel layers 120. In some implementations, the gate dielectric layer 116 and the gate structure 118 wrap around all four sides of the channel layers 120. In these implementations, the integrated circuit device 112 may be referred to as a nanostructure transistor such as a GAA transistor.

The channel layers 120 may include nanoscale layers of semiconductor material, such as silicon (Si), silicon germanium (SiGe), and/or doped silicon, among other examples. The channel layers 120 may be formed from silicon nanosheets that are formed as part of a nanosheet stack above the substrate layer 106.

In some implementations, the gate dielectric layer 116 includes a low dielectric constant (low-k) dielectric material such as silicon oxide (SiOx). In some implementations, the gate dielectric layer 116 includes a high dielectric constant (high-k) dielectric material such as hafnium oxide (HfOₓ).

The gate structure 118 may be located laterally between the source/drain regions 114. In some implementations, the gate structure 118 is formed of a polysilicon material. In these implementations, the polysilicon material may be doped with one or more types of dopants (e.g., p-type dopants, n-type dopants) to tune a work function of the gate structure 118.

In some implementations, the gate structure 118 is formed of one or more metal materials (e.g., tungsten (W), titanium (Ti), cobalt (Co), and/or another metal). In these implementations, the gate structure 118 may include one or more work function metal layers (e.g., p-type metal layers, n-type metal layers) for tuning the work function of the gate structure 118. The work function metal layer(s) may be included between the gate dielectric layer 116 and the gate structure 118.

A p-type work function metal layer may include one or more p-type metals, such as tungsten (W), cobalt (Co), titanium nitride (TiN), tungsten nitride (WN), and/or another metal having a work function that is greater than approximately 4.7 electron volts (eV), among other examples. A p-type work function metal layer may be included to tune the work function of the gate structure 118 such that the work function is adjusted close to the valence band of the material of the channel layers 120.

An n-type work function metal layer may include one or more metal materials that tune or adjust the work function of the gate structure 118 near the conduction band of the material of the channel layers 120 of the semiconductor device 100. In some implementations, an n-type work function metal layer may include titanium aluminum (TiAl). In some implementations, an n-type work function metal layer includes titanium aluminum carbon (TiAIC). In some implementations, an n-type work function metal layer includes another aluminum-containing metal. In some implementations, another n-type metal material is included in an n-type work function metal layer.

Various spacers may be included in the integrated circuit devices 112. For example, sidewall spacers 122 may be included on the sidewalls of the gate structure 118 to provide electrical isolation for the gate structure 118, among other examples. In some implementations, the sidewall spacers 122 are in contact with the gate dielectric layer 116 and the CESL 110. In some implementations, the sidewall spacers 122 are in contact with the work function metal layer. The ends of the channel layers 120 interfaced with a gate structure 118 may be aligned with outer sidewalls of the sidewall spacers 122 on opposing sides of the gate structure 118. The sidewall spacers 122 may include a silicon oxide (SiOₓ), a silicon nitride (SiₓN_{y}), a silicon oxycarbide (SiOC), a silicon oxycarbonitride (SiOCN), and/or another suitable material.

As another example, inner spacers 124 may be included laterally between the gate structure 118 and the source/drain regions 114 of an integrated circuit device 112. The inner spacer 124 may be included to reduce parasitic capacitance in the integrated circuit device 112 and to protect the source/drain regions 114 from being etched in a nanosheet release operation to remove sacrificial layers between the channel layers 120. The inner spacers 124 may include a silicon nitride (SiₓN_{y}), a silicon oxide (SiOx), a silicon oxynitride (SiON), a silicon oxycarbide (SiOC), a silicon carbon nitride (SiCN), a silicon oxycarbonitride (SiOCN), and/or another dielectric material.

The source/drain regions 114 are electrically coupled and/or physically coupled with source/drain contact structures 126. A source/drain contact structure 126 may extend through a portion of the dielectric layer 108 and an associated CESL 110. The source/drain contact structures 126 may include contact vias, contact plugs, and/or another type of contact structures that electrically connect the source/drain regions 114 of the integrated circuit devices 112 with the interconnect layer 104 of the semiconductor device 100. In some implementations, a source/drain contact structure 126 extends through an ILD layer 130 and/or an ESL 132 of the interconnect layer 104. In these implementations, the top surface of the source/drain contact structure 126 may be higher than the top surfaces of the gate structures 118 in the semiconductor device 100. In some implementations, a top surface of a source/drain contact structure 126 is approximately co-planar with the top surfaces of the gate structures 118.

The source/drain contact structures 126 include cobalt (Co), ruthenium (Ru), tungsten (W), molybdenum (Mo), copper (Cu), and/or another electrically conductive material or metal material. One or more liner layers 128 may be included on sidewalls of the source/drain contact structures 126. The liner layer(s) 128 may include a barrier layer that is included to prevent or minimize diffusion of materials from the source/drain contact structures 126 to the surrounding dielectric layers, an adhesion layer or glue layer that is included to promote adhesion between the source/drain contact structures 126 and the surrounding dielectric layers, and/or another type of liner. Examples of materials for the liner layer(s) 128 include titanium nitride (TiN), tantalum nitride (TaN), and/or another suitable liner material. Alternatively, the source/drain contact structures 126 may be free of liner layers and may contact the surrounding dielectric layers.

The interconnect layer 104 of the semiconductor device 100 is included above the device layer 102 and above the integrated circuit devices 112 in the z-direction in the semiconductor device 100. The interconnect layer 104 includes a plurality of dielectric layers that are arranged in a direction (e.g., the z-direction) that is approximately perpendicular to the substrate layer 106. The dielectric layers may include ILD layers 130 and ESLs 132 that are arranged in an alternating manner in the z-direction. The ILD layers 130 and the ESLs 132 may extend in the x-direction and/or in the y-direction in the semiconductor device 100.

The ILD layers 130 may each include an oxide (e.g., a silicon oxide (SiOₓ) and/or another oxide material), an undoped silicate glass (USG), a boron-containing silicate glass (BSG), a fluorine-containing silicate glass (FSG), tetraethyl orthosilicate (TEOS), hydrogen silsesquioxane (HSQ), and/or another suitable dielectric material. In some implementations, an ILD layer 130 includes an extreme low dielectric constant (ELK) dielectric material having a dielectric constant that is less than approximately 2.5. Examples of ELK dielectric materials include carbon doped silicon oxide (C-SiOₓ), amorphous fluorinated carbon (a-CₓF_{y}), parylene, bis-benzocyclobutenes (BCB), polytetrafluoroethylene (PTFE), a silicon oxycarbide (SiOC) polymer, porous hydrogen silsesquioxane (HSQ), porous methyl silsesquioxane (MSQ), porous polyarylether (PAE), and/or porous silicon oxide (SiOx), among other examples.

The ESLs 132 may each include a silicon nitride (SiₓN_{y}), silicon carbide (SiC), silicon oxynitride (SiON), and/or another suitable dielectric material. In some implementations, an ILD layer 130 and an ESL 132 include different dielectric materials to provide etch selectivity to enable various structures to be formed in the interconnect layer 104.

The interconnect layer 104 may further include a plurality of layers of conductive structures in the dielectric layers (e.g., the ILD layers 130 and the ESLs 132) of the interconnect layer 104. The conductive structures in the interconnect layer 104 may be interconnected to enable signals and/or power to be distributed throughout the semiconductor device 100 through the interconnect layer 104. The conductive structures include a combination of metallization structures 134 and interconnect structures 136. The metallization structures 134 may include trenches, conductive traces, and/or other types of conductive structures that primarily extend in the x-direction and/or in the y-direction in the interconnect layer 104. The interconnect structures 136 may include vias, plugs, conductive columns, and/or other types of conductive structures that primarily extend in the z-direction in the semiconductor device. In some implementations, a conductive structure in the interconnect layer 104 includes a dual damascene structure, which includes a combination of a metallization structure 134 and an interconnect structure 136.

The metallization structures 134 and the interconnect structures 136 may each include one or more electrically conductive materials such as tungsten (W), cobalt (Co), ruthenium (Ru), molybdenum (Mo), titanium (Ti), aluminum (Al), copper (Cu), gold (Au), and/or a combination thereof, among other examples of electrically conductive materials. In some implementations, one or more liner layers are included between the metallization structures 134 and/or the interconnect structures 136 and the surrounding dielectric layers in the interconnect layer 104.

The one or more liner layers may include barrier liners, adhesion liners, and/or another type of liners. Examples of materials for the one or more liners include tantalum nitride (TaN) and/or titanium nitride (TiN), among other examples. Alternatively, the metallization structures 134 and/or the interconnect structures 136 may be free of liner layers and may contact the surrounding dielectric layers.

In some implementations, the metallization structures 134 and the interconnect structures 136 of the interconnect layer 104 may be arranged in a vertical manner (e.g., in the z-direction). In other words, a plurality of stacked metallization structures 134 and interconnect structures 136 may extend between the device layer 102 and a top of the interconnect layer 104 to facilitate electrical signals and/or power to be routed between the device layer 102 and connection structures (not shown) of the semiconductor device 100.

The plurality of stacked metallization structures 134 may be arranged in layers that may be referred to as M-layers, and the plurality of stacked interconnect structures 136 may be arranged in layers that may be referred to as V-layers. A bottom-most layer of interconnect structures 136 in the interconnect layer 104 may be referred to as a VO layer. The VO layer may include source/drain interconnect structures 138 that are electrically coupled and/or physically coupled to the source/drain contact structures 126 of one or more integrated circuit devices 112. The VO layer may also include one or more gate interconnect structures 140 that are electrically coupled and/or physically coupled to the gate structures 118 of one or more integrated circuit devices 112. The source/drain interconnect structures 138 may be referred to source/drain vias (VDs), and the gate interconnect structures 140 may be referred to as gate vias (VGs). In some implementations, gate contacts (not shown) are included between the gate structures 118 and the gate interconnect structures 140.

In some implementations, the top surfaces of a source/drain interconnect structure 138 and a gate interconnect structure 140 are approximately co-planar in the interconnect layer 104. The gate interconnect structure 140 may be taller (or have a greater z-direction thickness) than the source/drain interconnect structure 138. Accordingly, the bottom surface of the gate interconnect structure 140 may be lower in the semiconductor device 100 than the bottom surface of the source/drain interconnect structure 138. The source/drain interconnect structure 138 may extend through an ILD layer 130 and an ESL 132, whereas the gate interconnect structure 140 may extend through a plurality of ILD layers 130 and/or a plurality of ESLs 132.

Additionally and/or alternatively, a source/drain interconnect structure 138 and a gate interconnect structure 140 may have approximately a same z-direction thickness, and may have approximately co-planar top surfaces and approximately co-planar bottom surfaces.

As further shown in FIG. 1A, in some implementations, the VO layer may include one or more merged interconnect structures 142. A merged interconnect structure 142 is a combination of a source/drain interconnect structure 138 and a gate interconnect structure 140. A portion of the merged interconnect structure 142 is located over and electrically coupled to a gate structure 118, and another portion of the merged interconnect structure 142 is located over and electrically coupled to a source/drain contact structure 126. Thus, the merged interconnect structure 142 electrically coupled the gate structure 118 and the source/drain contact structure 126 together.

The source/drain interconnect structures 138, the gate interconnect structures 140, and the merged interconnect structures 142 may each include one or more electrically conductive materials such as tungsten (W), cobalt (Co), ruthenium (Ru), molybdenum (Mo), titanium (Ti), aluminum (Al), copper (Cu), gold (Au), and/or a combination thereof, among other examples of electrically conductive materials. In some implementations, one or more liner layers are included between the source/drain interconnect structures 138, the gate interconnect structures 140, the merged interconnect structures 142 and the surrounding dielectric layers in the interconnect layer 104. The one or more liner layers may include barrier liners, adhesion liners, and/or another type of liners. Examples of materials for the one or more liners include tantalum nitride (TaN) and/or titanium nitride (TiN), among other examples. Alternatively, the source/drain interconnect structures 138, the gate interconnect structures 140, and/or the merged interconnect structures 142 may be free of liner layers and may contact the surrounding dielectric layers.

In some embodiments, the source/drain contact structures 126 and the source/drain interconnect structures 138 include the same conductive materials. In some embodiments, the source/drain contact structures 126 and the source/drain interconnect structures 138 include different conductive materials. In some embodiments, at least one of the source/drain contact structures 126 and the source/drain interconnect structures 138 are separated from the surrounding dielectric layers by a liner. In some embodiments, the source/drain interconnect structures 138 contacts to the surrounding dielectric layers (e.g., liner free).

A bottom-most layer of metallization structures 134 coupled to the bottom-most layer of interconnect structures 136 may be referred to as a metal-0 (MO) layer, and may be located above the bottom-most layer of interconnect structures 136 (e.g., the layer that includes the source/drain interconnect structures 138, the gate interconnect structures 140, and the merged interconnect structures 142) in the interconnect layer 104. Thus, the metallization structures 134 in the M0 layer may be electrically coupled and/or physically coupled with the source/drain interconnect structures 138, the gate interconnect structures 140, and/or the merged interconnect structures 142.

Additional layers of conductive structures may be arranged in a similar manner in the interconnect layer 104. For example, a layer of interconnect structures 136 may be referred to as a via-1 (V1) layer that is located above and electrically coupled and/or physically coupled to the layer of metallization structures 134 in the M0 layer. A layer of metallization structures 134 may be referred to as a metal-1 (M1) layer that is located above and electrically coupled and/or physically coupled to the layer of interconnect structures 136 in the V1 layer. A layer of interconnect structures 136 may be referred to as a via-2 (V2) layer that is located above and electrically coupled and/or physically coupled to the layer of metallization structures 134 in the M1 layer. A layer of metallization structures 134 may be referred to as a metal-2 (M2) layer that is located above and electrically coupled and/or physically coupled to the layer of interconnect structures 136 in the V2 layer. A layer of interconnect structures 136 may be referred to as a via-3 (V3) layer that is located above and electrically coupled and/or physically coupled to the layer of metallization structures 134 in the M2 layer. A layer of metallization structures 134 may be referred to as a metal-3 (M3) layer that is located above and electrically coupled and/or physically coupled to the layer of interconnect structures 136 in the V3 layer. A layer of interconnect structures 136 may be referred to as a via-4 (V4) layer that is located above and electrically coupled and/or physically coupled to the layer of metallization structures 134 in the M3 layer. A layer of metallization structures 134 may be referred to as a metal-4 (M4) layer that is located above and electrically coupled and/or physically coupled to the layer of interconnect structures 136 in the V4 layer. In some implementations, the interconnect layer 104 includes a different quantity of layers of metallization structures 134 and/or a different quantity of layers of interconnect structures 136 than the quantities shown in FIG. 1A.

FIG. 1B illustrates a top view of a portion of the semiconductor device 100. As shown in FIG. 1B, the gate structures 118 of the integrated circuit devices 112 of the semiconductor device 100 may extend in the y-direction across one or more fin structures 144 of the integrated circuit devices 112. The fin structures 144 include the stacks of channel layers 120 that extend in the x-direction. The source/drain regions 114 (not shown for purposes of clarity) of the integrated circuit devices 112 may be located on the fin structures 144 on opposing sides of a gate structure 118.

As further shown in FIG. 1B, a source/drain interconnect structure 138 may be located over a fin structure 144 laterally between gate structures 118 in the x-direction. A gate interconnect structure 140 may be located over a gate structure 118. A merged interconnect structure 142 may be located over a gate structure 118 and an adjacent source/drain contact structure 126.

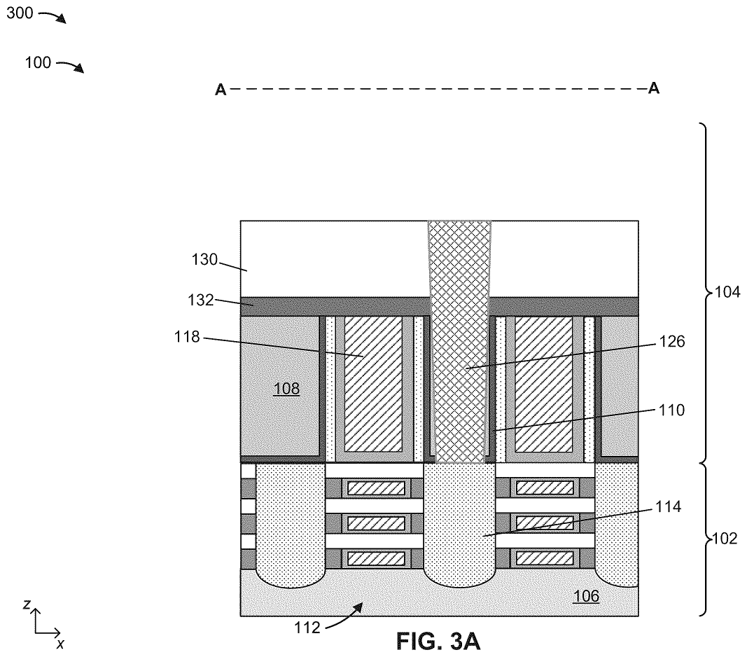

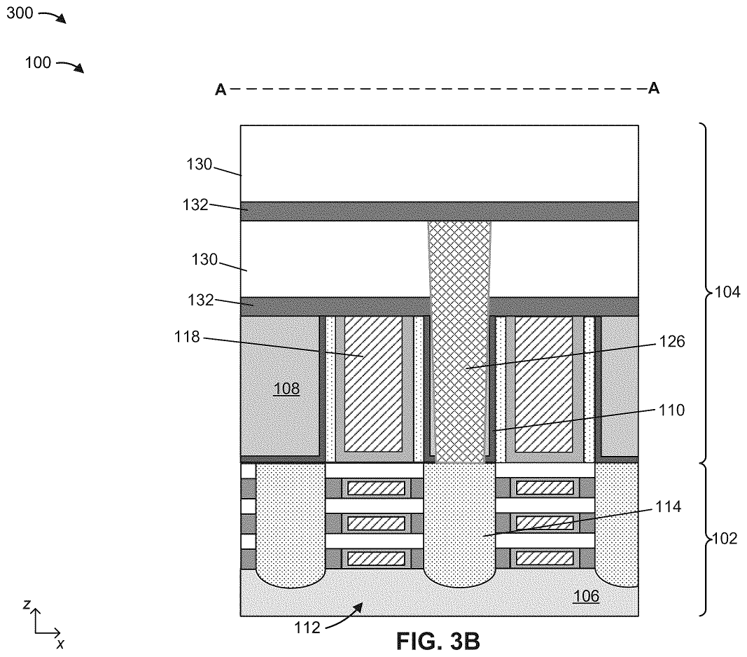

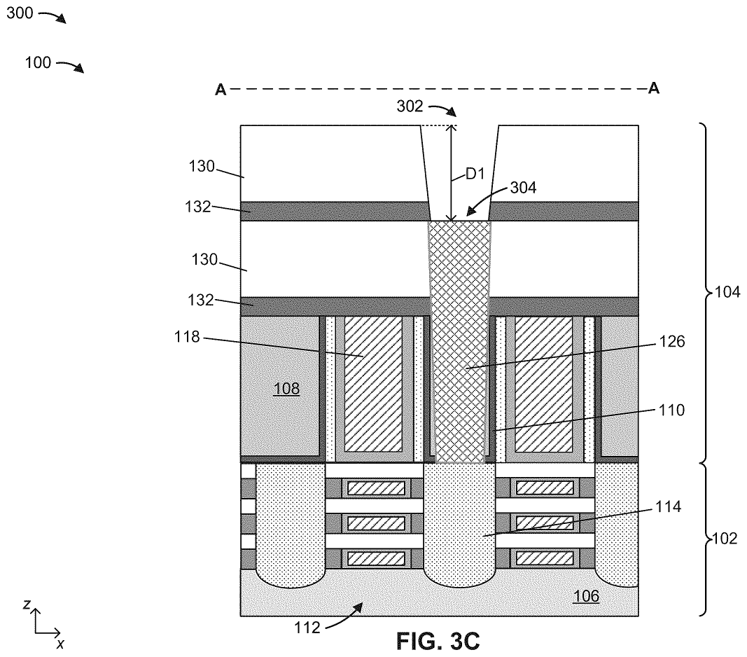

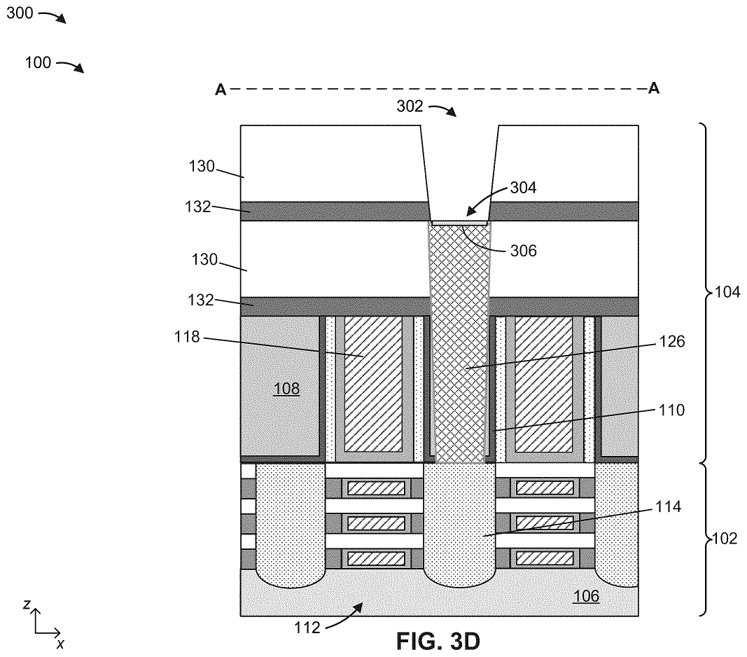

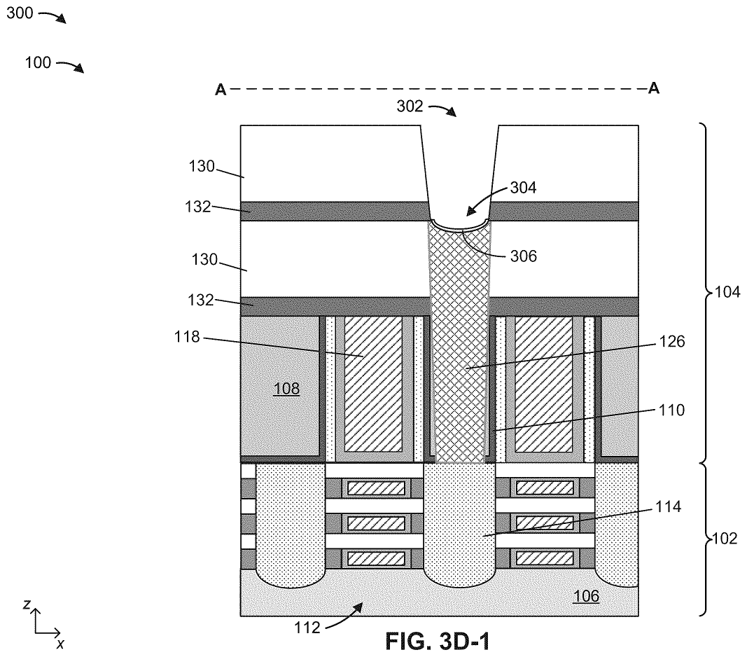

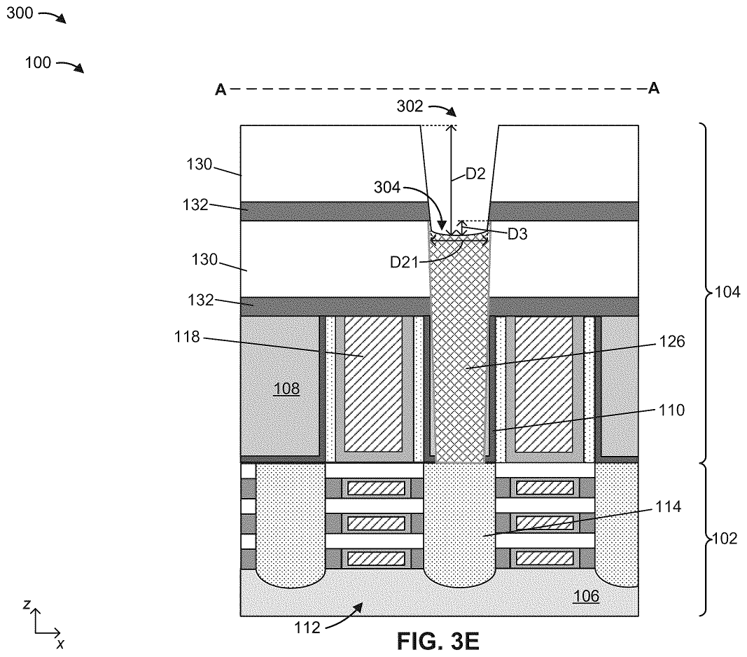

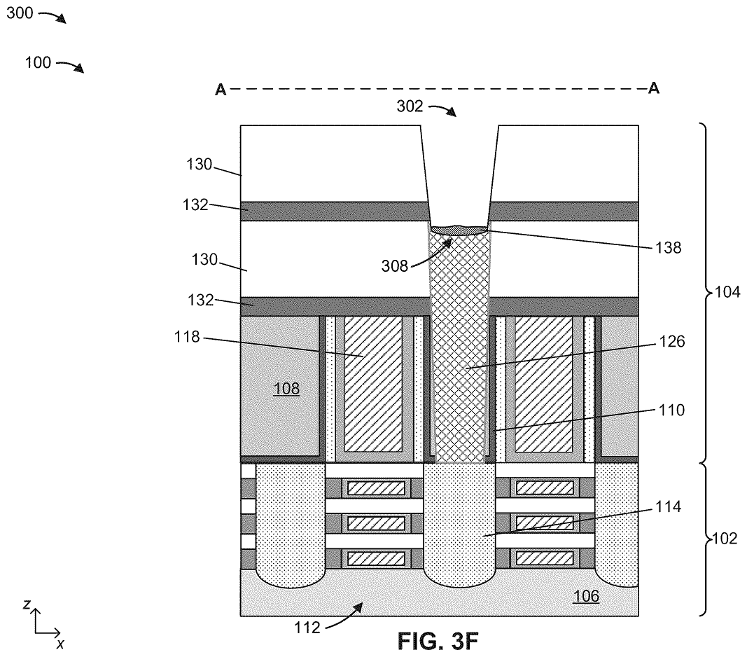

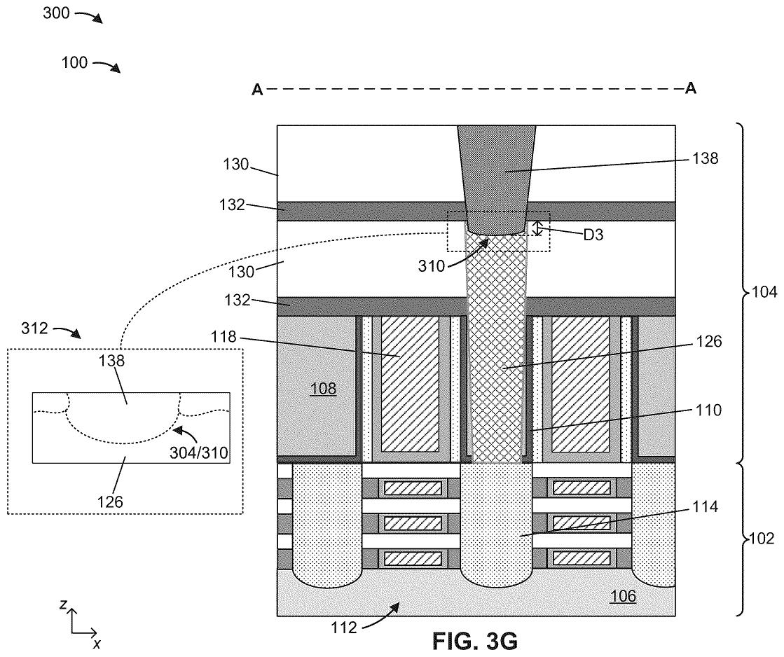

FIG. 1B further illustrates the locations of various cross-section views, including a cross-section view of a source/drain interconnect structure 138 along a line B-B, a cross-section view of a gate interconnect structure 140 along a line B-B, and a cross-section view of a merged interconnect structure 142 along line C-C. Such cross-section views may be illustrated in subsequent figures, such as FIGS. 3A-3G, 4A-4D, 5A-5D, 6A-6C, 7A-7F, and/or 8A-8F, among other examples.

As indicated above, FIGS. 1A and 1B are provided as an example. Other examples may differ from what is described with regard to FIGS. 1A and 1B.

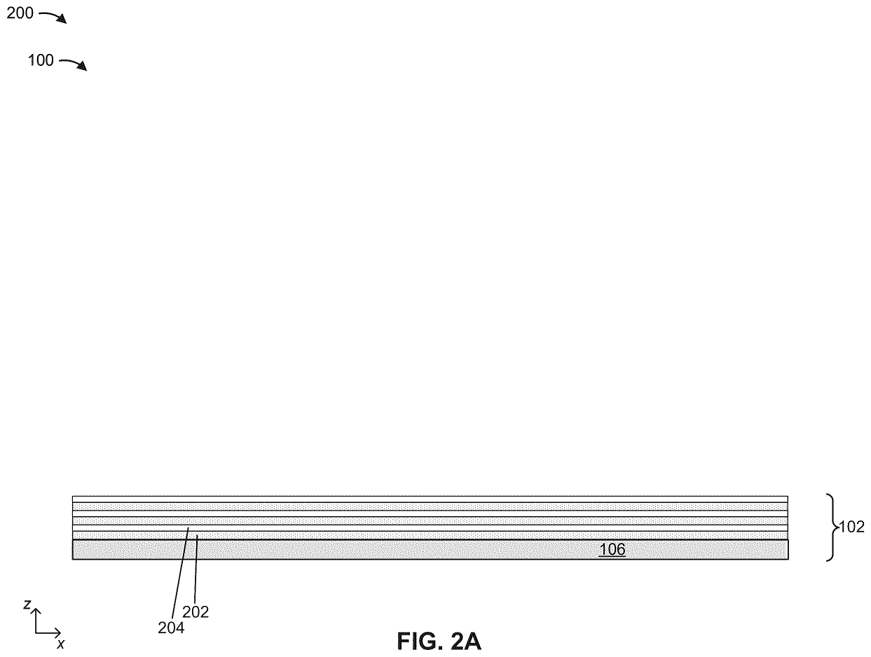

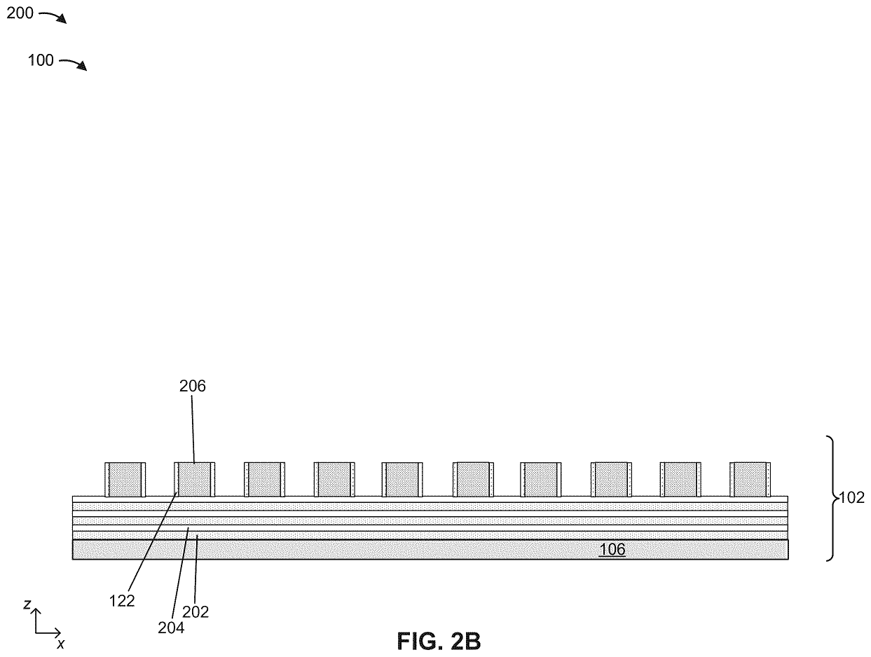

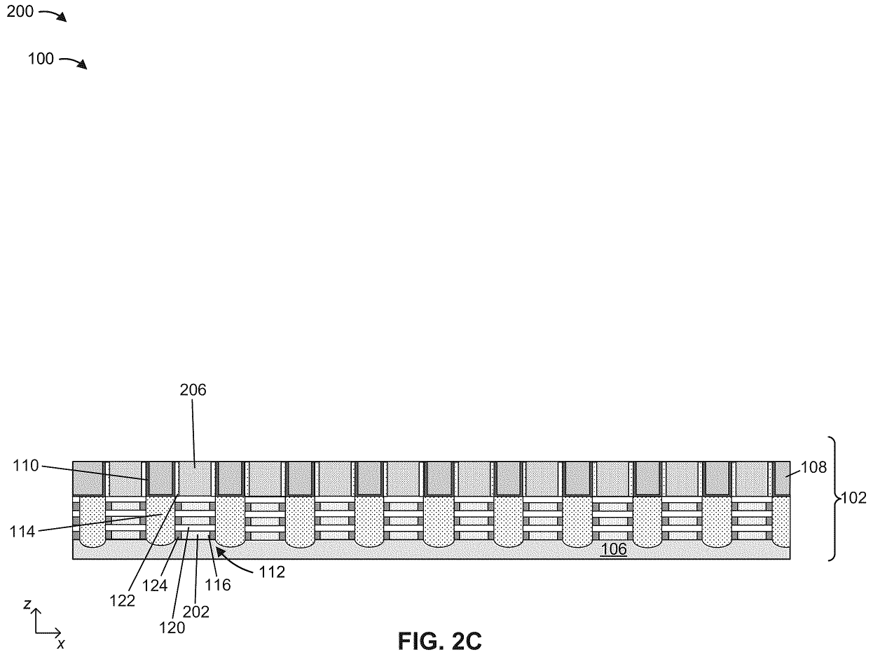

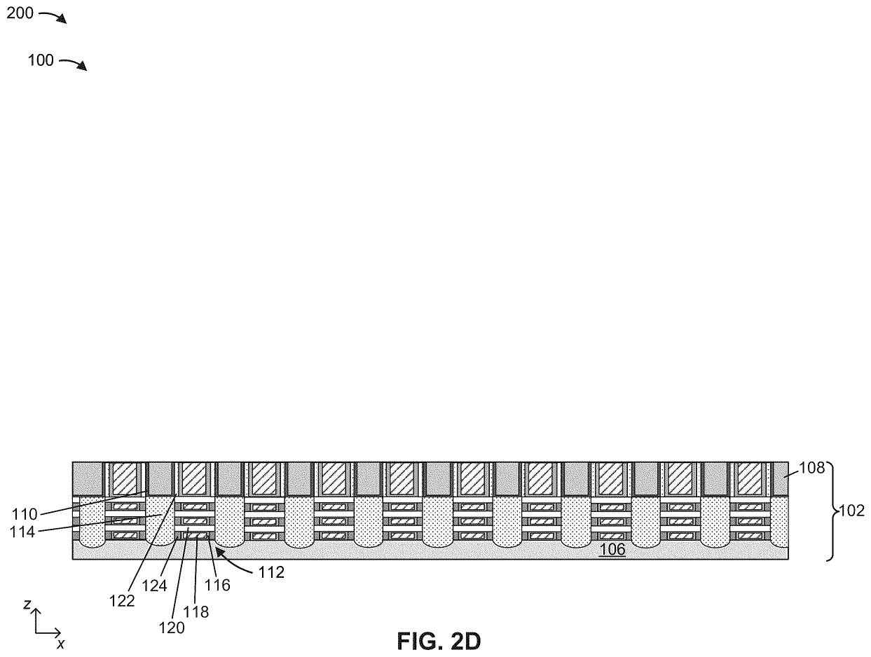

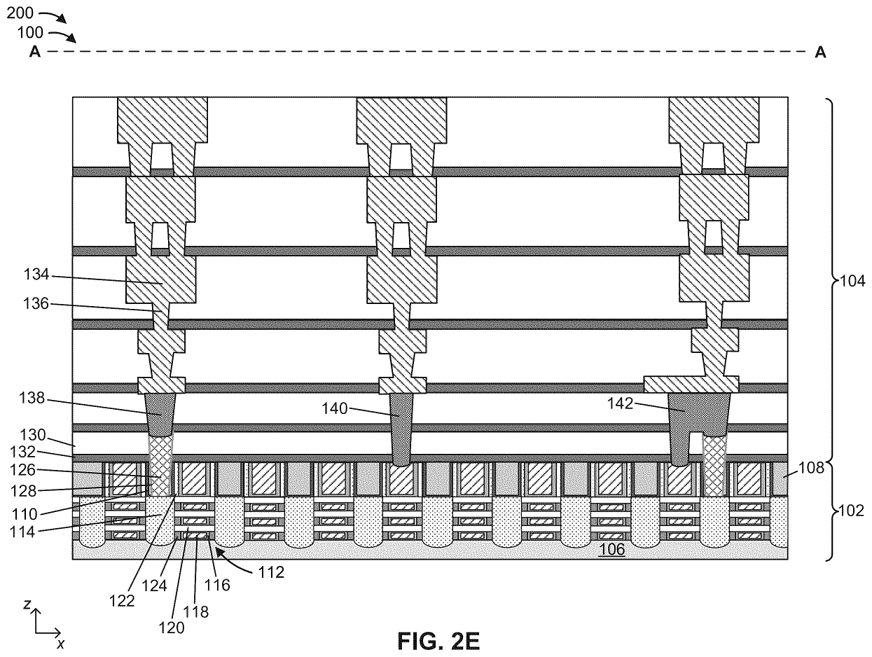

FIGS. 2A-2E are diagrams of an example implementation 200 of forming a device layer 102 (or a portion thereof) of the semiconductor device 100 described herein. In some implementations, one or more of the semiconductor processing operations described in connection with FIGS. 2A-2E may be performed using one or more semiconductor processing tools, such as a deposition tool, an exposure tool, a developer tool, an etch tool, a planarization tool, an ion implantation tool, a wafer/die transport tool, and/or another type of semiconductor processing tool.

As shown in FIG. 2A, the substrate layer 106 is provided. The substrate layer 106 may be provided in the form of a semiconductor wafer such as a silicon (Si) wafer, a silicon-on-insulator (SOI) wafer, and/or another type of semiconductor work piece. The semiconductor device 100 may be formed on the semiconductor wafer with other semiconductor devices.

A layer stack may be formed on the substrate layer 106. The layer stack may be referred to as a superlattice. The layer stack may include a plurality of alternating layers that are arranged in a direction (e.g., the z-direction) that is approximately perpendicular to the substrate layer 106. For example, the layer stack may include vertically alternating layers of sacrificial layers 202 and nanostructure channel layers 204 above the substrate layer 106. The quantity of the sacrificial layers 202 and the quantity of the nanostructure channel layers 204 illustrated in FIG. 2A are examples, and other quantities of the sacrificial layers 202 and the nanostructure channel layers 204 are within the scope of the present disclosure.

The sacrificial layers 202 enable a vertical distance to be defined between adjacent nanostructure channels that are formed from the nanostructure channel layers 204, and serve as placeholder layers for subsequently-formed gate structures of the integrated circuit devices 112 of the semiconductor device 100 that are formed around the nanostructure channels.

The sacrificial layers 202 include a first material composition, and the nanostructure channel layers 204 include a second material composition. In some implementations, the first material composition and the second material composition are the same material composition. In some implementations, the first material composition and the second material composition are different material compositions. As an example, the sacrificial layers 202 may include silicon germanium (SiGe) and the nanostructure channel layers 204 may include silicon (Si). This enables the sacrificial layers 202 and/or the nanostructure channel layers 204 to be selectively etched (e.g., enables the sacrificial layers 202 and not the nanostructure channel layers 204 to be etched, enables the nanostructure channel layers 204 and not the sacrificial layers 202 to be etched) depending on the type of etchant that is used.

One or more types of deposition tools may be used to deposit and/or grow the alternating layers of the layer stack to include nanostructures (e.g., nanosheets) on the substrate layer 106. For example, a deposition tool may be used to grow the sacrificial layers 202 and/or the nanostructure channel layers 204 by epitaxial growth, which may include epitaxy techniques such as a molecular beam epitaxy (MBE), metalorganic chemical vapor deposition (MOCVD) process, and/or another suitable epitaxy technique. Additionally and/or alternatively, the sacrificial layers 202 and/or the nanostructure channel layers 204 may be deposited by chemical vapor deposition (CVD), physical vapor deposition (PVD), atomic layer deposition (ALD), and/or another suitable deposition technique.

In the y-direction, which is not visible in the view in FIG. 2A, the layer stack and the substrate layer 106 may be etched to form fin structures that extend in the x-direction. A fin structure may include a portion of the layer stack and a portion of the substrate layer 106 under the layer stack. The fin structures may be formed by patterning the one or more masking layers and etching based on a pattern formed in one or more of the masking layers. The one or more masking layers may be patterned using photolithography techniques, including double-patterning or multi-patterning techniques. An etch tool may be used to etch the layer stack and the substrate layer 106 based on the pattern using a dry etch technique (e.g., reactive ion etching), a wet etch technique, and/or a combination thereof. In some implementations, shallow trench isolation (STI) regions (not shown) may be formed between adjacent fin structures in the y-direction.

As shown in FIG. 2B, dummy gate structures 206 (also referred to as dummy gate stacks or temporary gate structures) may be formed over portions of the layer stack of sacrificial layers 202 and nanostructure channel layers 204. The dummy gate structures 206 may extend in the y-direction and may be arranged in the x-direction such that the dummy gate structures 206 are approximately perpendicular to the fin structures. The dummy gate structures 206 are sacrificial structures that are to be replaced by replacement gate structures or replacement gate stacks at a subsequent processing stage for the integrated circuit devices 112 of the semiconductor device 100. The dummy gate structures 206 may also be used to define source/drain (S/D) recesses in which source/drain regions of the nanostructure transistors are formed in the layer stack of sacrificial layers 202 and nanostructure channel layers 204.

The dummy gate structures 206 may include polycrystalline silicon (polysilicon or PO) or another material. The layers of the dummy gate structures 206 may be formed using various semiconductor processing techniques such depositing the layers of the dummy gate structures 206, patterning the layers of the dummy gate structures 206 to define the dummy gate structures 206, and/or other semiconductor processing techniques. The sidewall spacers 122 may be formed on the sidewalls of the dummy gate structures 206.

As shown in FIG. 2C, the source/drain regions 114 of the integrated circuit devices 112 are formed in the layer stack of sacrificial layers 202 and nanostructure channel layers 204. To form the source/drain regions 114, source/drain recesses may be formed through the layer stack of sacrificial layers 202 and nanostructure channel layers 204 in an etch operation. The source/drain recesses may be formed on opposing sides of a dummy gate structure 206 in the x-direction. The etch operation may be performed using the etch tool and may be referred to a strained source/drain (SSD) etch operation. In some implementations, the etch operation includes the use of a plasma etch technique, a wet chemical etch technique, and/or another type of etch technique.

Formation of the source/drain recesses may define the channel layers 120. The channel layers 120 may include silicon-based nanostructures (e.g., nanosheets or nanowires, among other examples) that function as the semiconductive channels of the integrated circuit devices 112 of the semiconductor device 100. The channel layers 120 are arranged in a direction (e.g., the z-direction) that is approximately perpendicular to the substrate layer 106. In other words, the channel layers 120 are vertically arranged or stacked above the substrate layer 106.

Prior to formation of the source/drain regions 114 in the source/drain recesses, the ends of the sacrificial layers 202 that are exposed in the source/drain recesses may be laterally etched in an etch operation, thereby forming cavities in the ends of the sacrificial layers 202. The inner spacers 124 may be formed in the cavities. To form the inner spacers 124, a deposition tool may be used to deposit a layer of dielectric material in the cavities and along the sidewalls and bottom surface of the source/drain recesses. A CVD technique, a PVD technique, and ALD technique, and/or another deposition technique may be used to deposit the layer of dielectric material. An etch tool is used to subsequently remove excess material of the layer of dielectric material from the source/drain recesses such that remaining portions correspond to the inner spacers 124 in the cavities.

After formation of the inner spacers 124, the source/drain recesses may be filled with one or more layers of epitaxial material to form the source/drain regions 114 in the source/drain recesses. For example, a deposition tool may be used to deposit a buffer region at the bottom of the source/drain recess, and a deposition tool may deposit a source/drain region 114 on the buffer region in the source/drain recess. In some implementations, a deposition tool is used to deposit a capping layer on the source/drain region 114 in the source/drain recess. As another example, a deposition tool may epitaxially grow a first layer of a source/drain region 114 (referred to as an L1) over an associated buffer region (which may be referred to as an LO), and may epitaxially grow a second layer of the source/drain region 114 (referred to as an L2, an L2-1, and/or an L2-2) over the first layer. The first layer may include a lightly doped silicon (e.g., doped with boron (B), phosphorous (P), and/or another dopant), and may be included as shielding layer to reduce short channel effects in the semiconductor device 100 and to reduce dopant extrusion or migration into the channel layers 120. The second layer may include a highly doped silicon or highly doped silicon germanium. The second layer may be included to provide a compressive stress in the source/drain regions 114 to reduce boron loss.

As further shown in FIG. 2C, the dielectric layer 108 may be formed over the source/drain regions 114 and around the dummy gate structures 206. The dielectric layer 108 may fill in areas between the dummy gate structures 206. In some implementations, a contact etch stop layer (CESL) is conformally deposited (e.g., by a deposition tool) over the source/drain regions 114 prior to formation of the dielectric layer 108. The dielectric layer 108 is then formed on the CESL. The CESL may provide a mechanism to stop an etch process when forming source/drain contact structures 126 for the source/drain regions 114. The CESL may be formed of a dielectric material having a different etch selectivity from adjacent layers or components. The CESL may include or may be a nitrogen containing material, a silicon containing material, and/or a carbon containing material. Furthermore, the CESL may include or may be silicon nitride (SiₓN_{y}), silicon carbon nitride (SiCN), carbon nitride (CN), silicon oxynitride (SiON), silicon carbon oxide (SiCO), or a combination thereof, among other examples. The CESL may be deposited using a deposition process, such as ALD, CVD, or another deposition technique.

As shown in FIG. 2D, a replacement gate process may be performed to replace the dummy gate structures 206 with the gate structures 118 of the integrated circuit devices 112. A dummy gate removal operation may be performed to remove the dummy gate structures 206 from the semiconductor device 100. The removal of the dummy gate structures 206 leaves behind openings (or recesses) in the dielectric layer 108, and provides access to the underlying sacrificial layers 202. The dummy gate structures 206 may be removed in one or more etch operations. Such etch operations may include a plasma etch technique, a wet chemical etch technique, and/or another type of etch technique.

The replacement gate process may include a nanostructure release operation (e.g., an SiGe release operation). The nanostructure release operation is performed to remove the sacrificial layers 202 (e.g., the silicon germanium layers). This results in openings between the channel layers 120 (e.g., the areas around the channel layers 120). The sacrificial layers 202 may be removed through the spaces that were previously occupied by the dummy gate structures 206. The nanostructure release operation may include the use of an etch tool to perform an etch operation to remove the sacrificial layers 202 based on a difference in etch selectivity between the material of the sacrificial layers 202 and the material of the channel layers 120, and between the material of the sacrificial layers 202 and the material of the inner spacers 124. The inner spacers 124 may function as etch stop layers in the etch operation to protect the source/drain regions 114 from being etched.

The replacement gate operation includes forming gate dielectric layers 116 and gate structures (e.g., replacement gate structures) 116 of the integrated circuit devices 112 in the openings between the source/drain regions 114 and between the inner spacers 124. In particular, the gate dielectric layers 116 and the gate structures 118 fill the areas between and around the channel layers 120 that were previously occupied by the sacrificial layers 202 such that the gate structures 118 fully wrap around the channel layers 120 and surround the channel layers 120.

This increases control of the channel layers 120, increases drive current for the integrated circuit devices 112, and/or reduces short channel effects (SCEs) for the integrated circuit devices 112, among other examples. The gate structures 118 may also fill in the spaces that were previously occupied by the dummy gate structures 206. Portions of a gate structure 118 are formed in between pairs of channel layers 120 in an alternating vertical arrangement. In other words, the semiconductor device 100 includes one or more vertical stacks of alternating channel layers 120 and portions of a gate structure 118.

As shown in FIG. 2E, the source/drain contact structures 126 of the integrated circuit devices 112 may be formed through the dielectric layer 108. To form the source/drain contact structures 126, an ILD layer 130 and an ESL 132 of the interconnect layer 104 may be formed, and the recesses may be formed through the ILD layer 130, the ESL 132, and the dielectric layer 108, and the source/drain contact structures 126 may be formed in recesses.

In some implementations, a pattern in a photoresist layer is used to etch the ILD layer 130, the ESL 132, and/or the dielectric layer 108 to form the recesses. In these implementations, a deposition tool may be used to form the photoresist layer on the ILD layer 130. An exposure tool may be used to expose the photoresist layer to a radiation source to pattern the photoresist layer. A developer tool may be used to develop and remove portions of the photoresist layer to expose the pattern. An etch tool may be used to etch the ILD layer 130, the ESL 132, and/or the dielectric layer 108 based on the pattern to form the recesses. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer 108 based on a pattern to form the recesses.

The source/drain contact structures 126 may be formed in the recesses such that the source/drain contact structures 126 land on the source/drain regions 114. A deposition tool may be used to deposit the material of the source/drain contact structures 126 in the recesses using a CVD technique, a PVD technique, an ALD technique, an electroplating technique, and/or another suitable deposition technique. The material of the source/drain contact structures 126 may be deposited in one or more deposition operations. In some implementations, a seed layer is first deposited, and the material of the source/drain contact structures 126 is deposited on the seed layer. In some implementations, one or more liner layers 128 are deposited in the recesses, and the source/drain contact structures 126 are deposited on the liner layer(s) 128. In some implementations, a planarization tool is used to perform a planarization operation (e.g., a chemical-mechanical planarization (CMP) operation) to planarize the source/drain contact structures 126 after the source/drain contact structures 126 are deposited such that the tops of the source/drain contact structures 126 are approximately co-planar with the top of the ILD layer 130.

As further shown in FIG. 2E, the interconnect layer 104 of the semiconductor device 100 may be formed above the device layer 102. One or more deposition tools are used to deposit alternating layers of ILD layers 130 and ESLs 132 in the interconnect layer 104 of the semiconductor device 100. In this way, the ILD layers 130 and ESLs 132 may be arranged in the z-direction in the semiconductor device 100. One or more deposition tools may be used to deposit each of the ILD layers 130 and each of the ESLs 132 using a PVD technique, an ALD technique, a CVD technique, an oxidation technique, and/or another suitable deposition technique. In some implementations, a planarization tool may be used to planarize the ILD layers 130 and/or the ESLs 132 after the ILD layers 130 and/or the ESLs 132 are deposited.

As further shown in FIG. 2E, a deposition tool, an exposure tool, a developer tool, an etch tool, a planarization tool, a plating tool, and/or another semiconductor processing tool may be used to perform various operations to form the source/drain interconnect structures 138, the gate interconnect structures 140, and/or the merged interconnect structures 142 at the bottom of the interconnect layer 104. A plurality of layers of metallization structures 134 and a plurality of layers of interconnect structures 136 may be formed above the source/drain interconnect structures 138, the gate interconnect structures 140, and/or the merged interconnect structures 142 at the bottom of the interconnect layer 104.

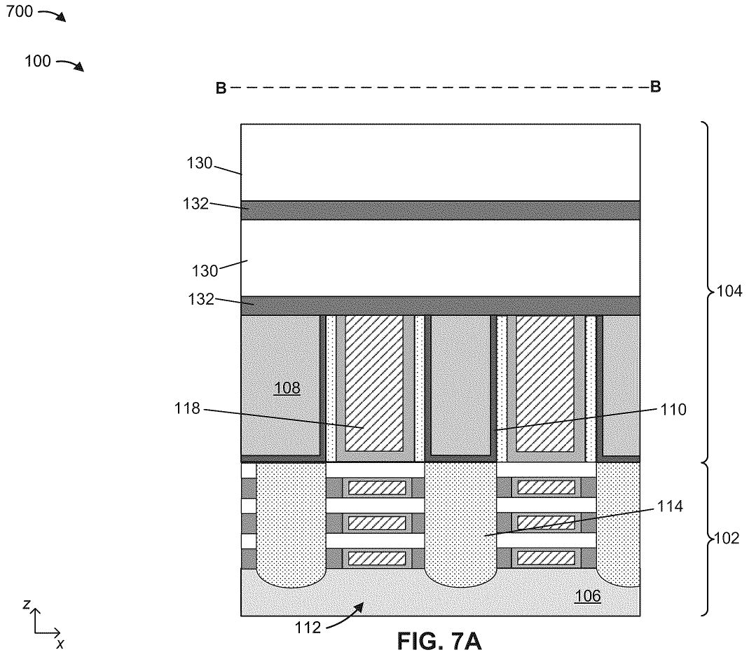

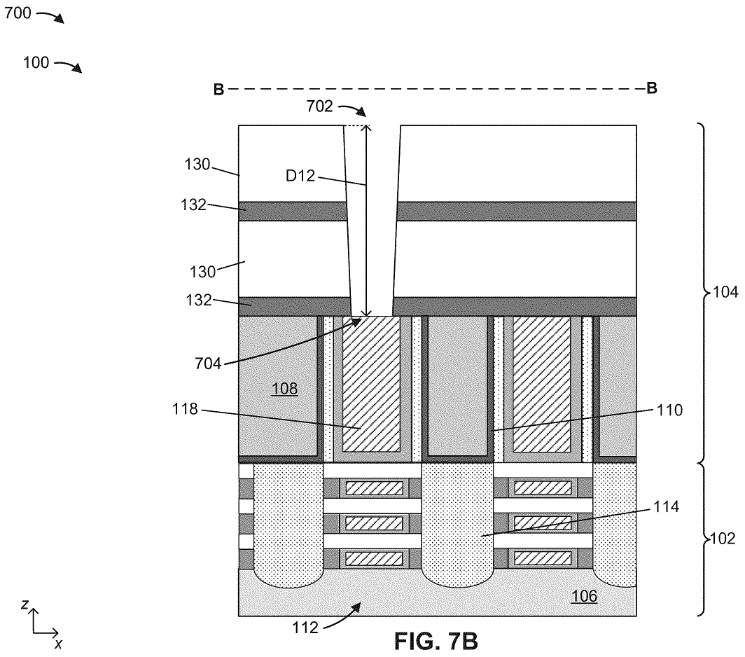

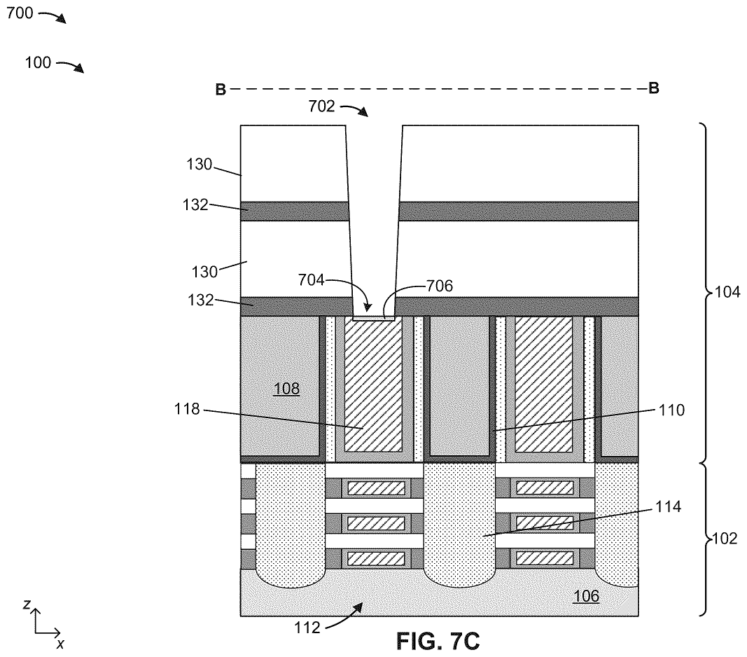

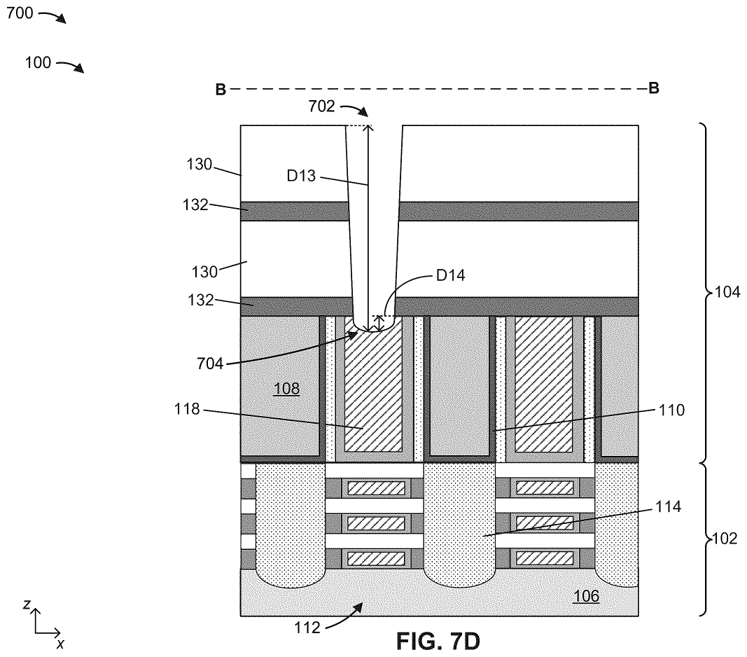

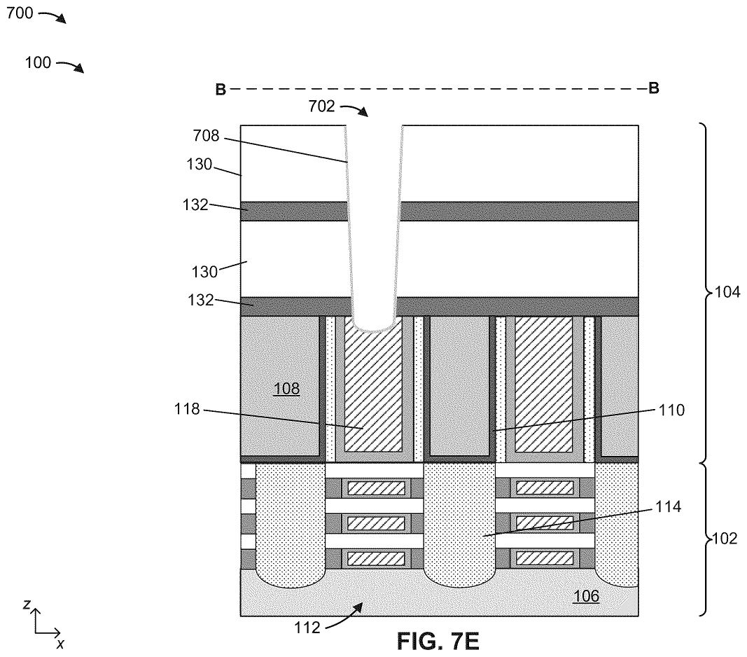

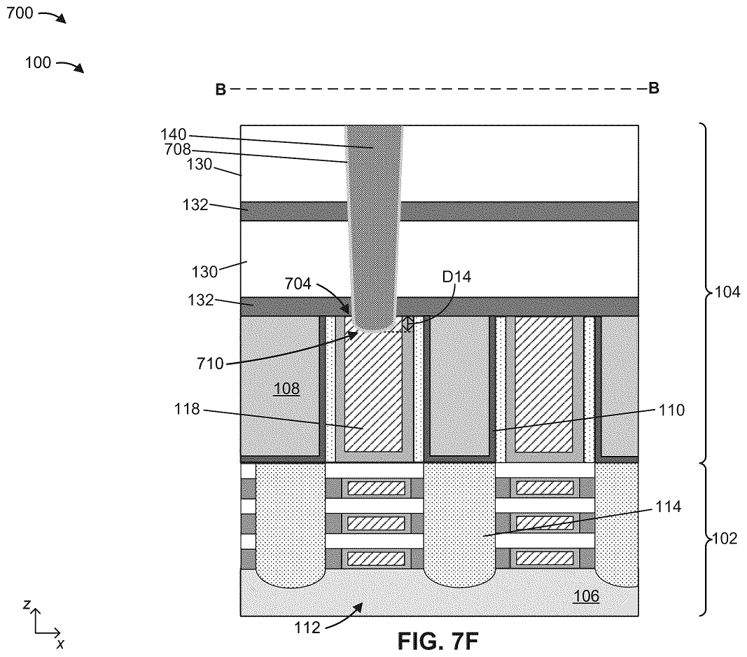

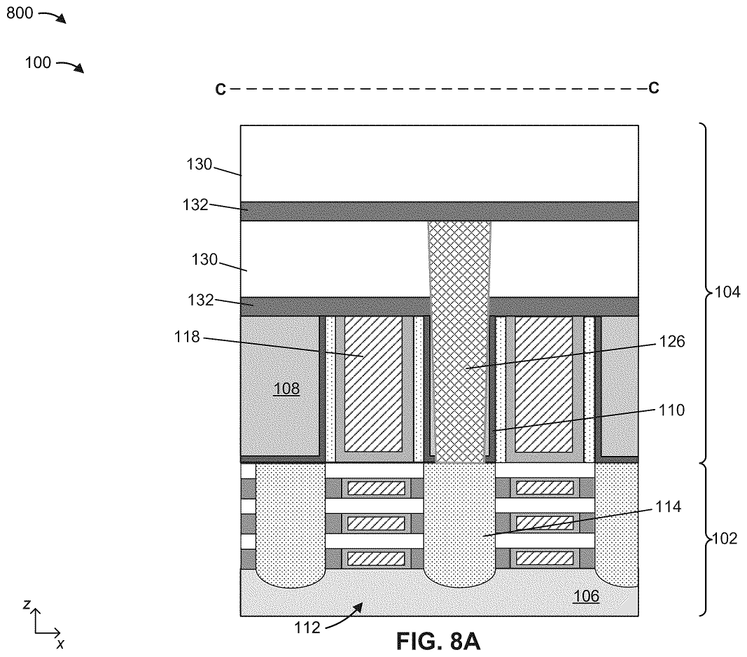

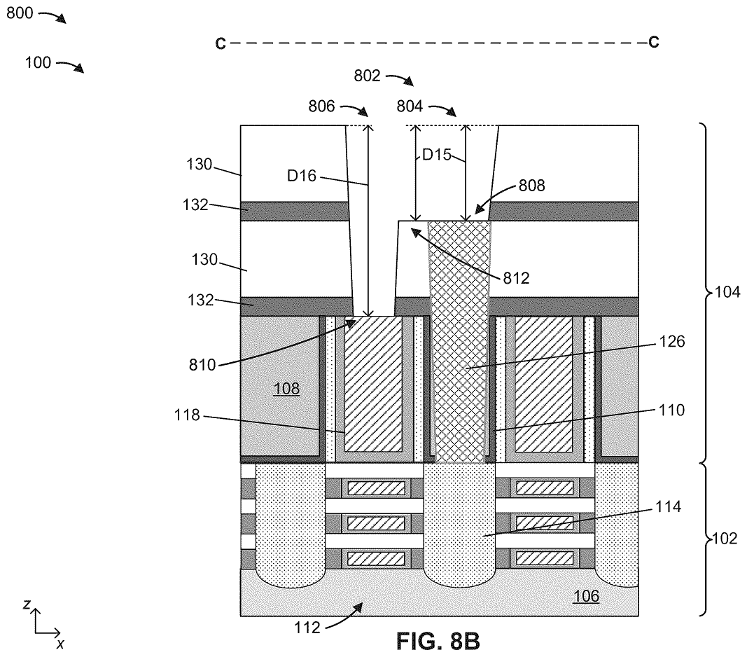

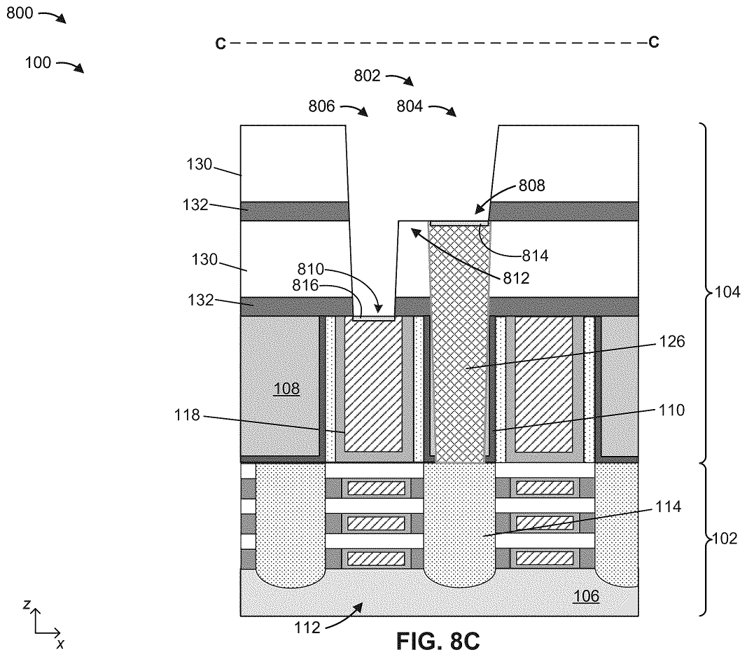

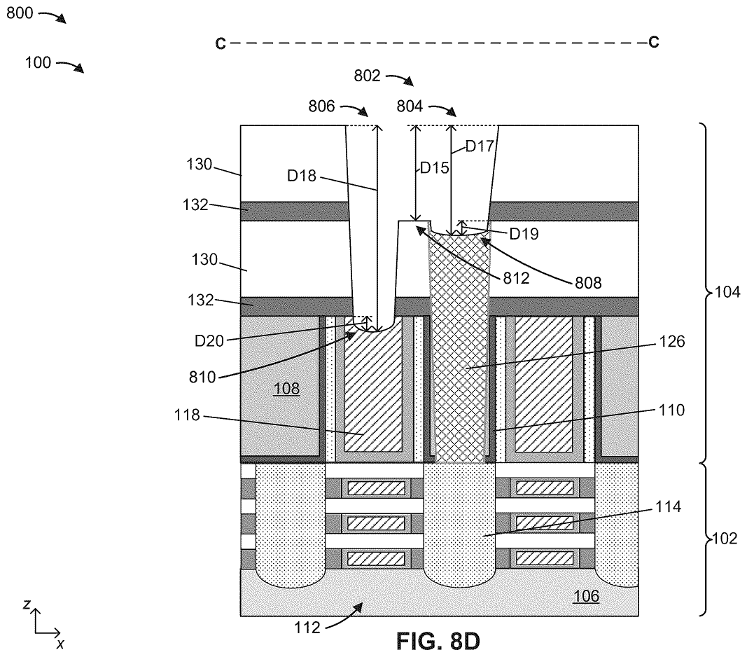

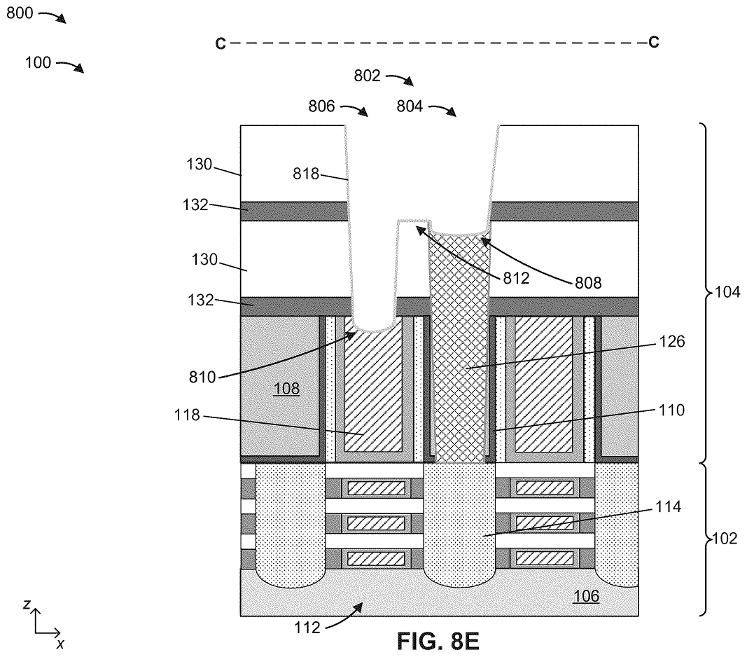

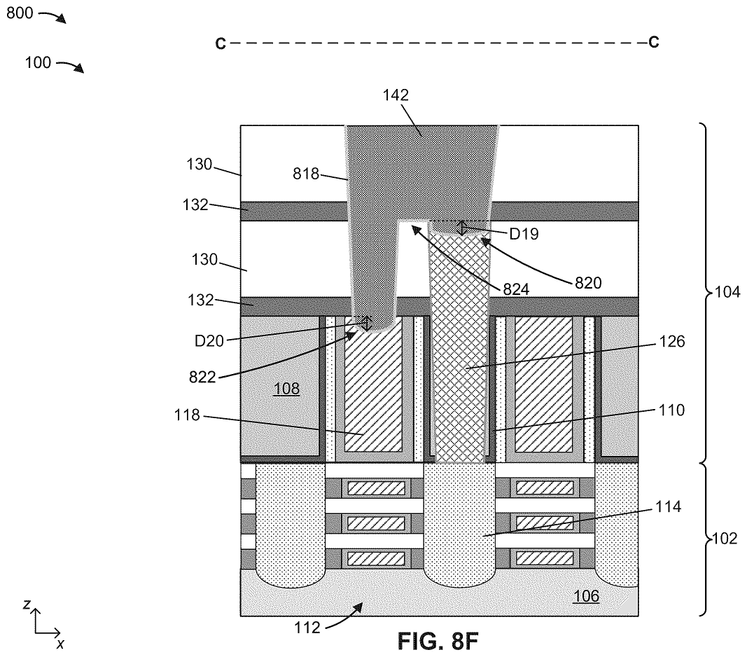

To form the interconnect layer 104, one or more ILD layers 130 and one or more ESLs 132 may be formed (e.g., using one or more deposition tools and/or one or more planarization tools) over the dielectric layer 108. Recesses may be formed in and/or through the ILD layer(s) 130 and the ESL(s) 132 (e.g., using an exposure tool, a developer tool, and/or an etch tool), and electrically conductive material may be deposited in the recesses in the ILD layer(s) 130 and the ESL(s) 132 (e.g., using one or more deposition tools and/or one or more planarization tools) to form the source/drain interconnect structures 138, the gate interconnect structures 140, and/or the merged interconnect structures 142. Example implementations of forming source/drain interconnect structures 138 are illustrated and described in connection with FIGS. 3A-3G, 4A-4D, 5A-5D, and 6A-6C. An example implementation of forming gate interconnect structures 140 is illustrated and described in connection with FIGS. 7A-7F. An example implementation of forming merged interconnect structures 142 is illustrated and described in connection with FIGS. 8A-8F.

A deposition tool, an exposure tool, a developer tool, an etch tool, a planarization tool, a plating tool, and/or another semiconductor processing tool may be used to perform various operations to form the metallization structures 134 and to form the interconnect structures 136 in the interconnect layer 104 of the semiconductor device 100. In some implementations, the metallization structures 134 and the interconnect structures 136 are formed in a plurality of vertically-arranged layers in the interconnect layer 104. For example, an ILD layer 130 and an ESL 132 may be formed (e.g., using one or more deposition tools and/or one or more planarization tools), recesses may be formed in and/or through the ILD layer 130 and the ESL 132 (e.g., using an exposure tool, a developer tool, and/or an etch tool), and a layer of metallization structures 134 (e.g., the M0 layer) may be formed in the ILD layer 130 and the ESL 132 (e.g., using one or more deposition tools and/or one or more planarization tools) above the layer of source/drain interconnect structures 138, gate interconnect structures 140, and/or merged interconnect structures 142. Another ILD layer 130 and another ESL 132 may be formed, and a layer of interconnect structures 136 (e.g., the V1 layer) may be formed in the ILD layer 130 and the ESL 132. Additional layers of metallization structures 134 and additional layers of interconnect structures 136 may be formed in a similar manner.

One or more deposition tools may be used to deposit the metallization structures 134 and/or the interconnect structures 136 using a PVD technique, an ALD technique, a CVD technique, an electroplating technique (e.g., an electro-chemical plating technique), and/or another suitable deposition technique. In some implementations, a planarization tool may be used to planarize the metallization structures 134 and/or the interconnect structures 136 after the metallization structures 134, and/or the interconnect structures 136 are deposited.

As indicated above, FIGS. 2A-2E are provided as an example. Other examples may differ from what is described with regard to FIGS. 2A-2E.

FIGS. 3A-3G are diagrams of an example implementation 300 of forming an interconnect layer 104 (or a portion thereof) of the semiconductor device 100 described herein. In particular, the example implementation 300 includes an example of forming a source/drain interconnect structure 138 in the interconnect layer 104 (e.g., the back end region or BEOL region) of the semiconductor device 100.

In some implementations, one or more of the semiconductor processing operations described in connection with FIGS. 3A-3G may be performed as part of the process of forming the semiconductor device 100 illustrated and described in connection with FIGS. 2A-2E. For example, one or more of the semiconductor processing operations described in connection with FIGS. 3A-3G may be performed as part of the process of forming the interconnect layer 104 shown in FIG. 2E. One or more of the semiconductor processing operations described in connection with FIGS. 3A-3G may be performed using one or more semiconductor processing tools, such as a deposition tool, an exposure tool, a developer tool, an etch tool, a planarization tool, an ion implantation tool, a wafer/die transport tool, and/or another type of semiconductor processing tool.

As shown in FIG. 3A, the interconnect layer 104 of the semiconductor device 100 is formed above the dielectric layer 108 of the device layer 102. Forming the interconnect layer 104 may include forming a first ESL 132 and a first ILD layer 130 over and/or on the dielectric layer 108 such that the first ESL 132 and the first ILD layer 130 cover the gate structures 118 of the integrated circuit devices 112. A deposition tool may be used to deposit the first ESL 132 and/or the first ILD layer 130 using a PVD technique, an ALD technique, a CVD technique, an oxidation technique, and/or another suitable deposition technique. The first ESL 132 and/or the first ILD layer 130 may be deposited in one or more deposition operations. In some implementations, a planarization tool may be used to perform a planarization operation (e.g., a CMP operation) to planarize the first ESL 132 and/or the first ILD layer 130 after the first ESL 132 and/or the first ILD layer 130 is deposited. A recess may be formed in and/or through the first ILD layer 130 and the first ESL 132 such that a source/drain region 114, and a source/drain contact structure 126 may be formed in the recess such that the source/drain contact structure 126 lands on the underlying source/drain region 114.

As shown in FIG. 3B, a second ESL 132 and a second ILD layer 130 may be over the source/drain contact structure 126 such that the second ESL 132 and the second ILD layer 130 cover the source/drain contact structure 126. A deposition tool may be used to deposit the second ESL 132 and/or the second ILD layer 130 using a PVD technique, an ALD technique, a CVD technique, an oxidation technique, and/or another suitable deposition technique. The second ESL 132 and/or the second ILD layer 130 may be deposited in one or more deposition operations. In some implementations, a planarization tool may be used to perform a planarization operation (e.g., a CMP operation) to planarize the second ESL 132 and/or the second ILD layer 130 after the second ESL 132 and/or the second ILD layer 130 is deposited.

As shown in FIG. 3C, a recess 302 may be formed over the source/drain contact structure 126 to expose a top surface 304 of the source/drain contact structure 126 through the second ILD layer 130 and the second ESL 132. In some implementations, a pattern in a photoresist layer is used to etch the second ILD layer 130 and/or the second ESL 132 to form the recess 302. In these implementations, a deposition tool may be used to form the photoresist layer on the second ILD layer 130 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern.

An etch tool may be used to etch the second ILD layer 130 and/or the second ESL 132 based on the pattern to form the recess 302 to a first depth indicated in FIG. 3C as a dimension D1. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recess 302 based on a pattern.

As shown in FIG. 3D, an impurity layer 306 may form in the top surface 304 of the source/drain contact structure 126. The impurity layer 306 may include a carbon (C) residue, a tungsten nitride (WN) byproduct, a tungsten oxide (WOₓ) byproduct, and/or another type of impurity that is driven into the top surface 304 as opposed to a native oxide that grows on top of the top surface 304.

The impurity layer 306 may increase the contact resistance between the source/drain contact structure 126 and the source/drain interconnect structure 138 that is to be formed in the recess 302, and/or may increase the likelihood of corrosion of the metal material of the source/drain interconnect structure 138.

FIG. 3D-1 illustrates an alternative implementation in which the top surface 304 of the source/drain contact structure 126 and the impurity layer 306 that forms on the top surface 304 are concave. A portion of source/drain contact structure 126 may be removed during dry etch process and a concave top surface 304 is formed.

Accordingly, and as shown in FIG. 3E, in some implementations, a wet cleaning operation and a wet etch operation may be performed to etch the top surface 304 to remove the impurity layer 306. Additionally and/or alternatively, dry etching may be used to remove the impurity layer 306. The removal of the impurity layer 306 results in the top surface 304 of the source/drain contact structure 126 being concave and recessed below the bottom surface of the second ESL 132 and into the first ILD layer 130. Thus, the depth of the recess 302 may be increased from the first depth (dimension D1) to a second depth (indicated in FIG. 3E as a dimension D2) that is greater than the first depth. In some implementations, the depth of the concavity or recess in the top surface 304 of the source/drain contact structure 126 (indicated in FIG. 3E as a dimension D3) may be included in a range of approximately 1 nanometer to approximately 20 nanometers to achieve a high likelihood that the impurity layer 306 is fully removed. However, other values and ranges are within the scope of the present disclosure. The bottom of the recess 302 may have a lateral width corresponding to a dimension D21, which may be included in a range of approximately 10 nanometers to approximately 20 nanometers.

However, other values and ranges are within the scope of the present disclosure. In some implementations, a ratio of the depth of the recess in the top surface 304 to a lateral width of the bottom of the recess 302 (e.g., D3:D21) may be included in a range of approximately 0.5:1 to approximately 1:1 to ensure full removal of the impurity layer 306. However, other values and ranges are within the scope of the present disclosure.

The wet cleaning operation and the wet etch operation may include the use of an etch tool. The semiconductor device 100 is placed in a processing chamber of the etch tool. For the wet cleaning operation, a wet cleaning agent such as isopropyl alcohol (IPA) may be provided into the recess 302 to clean process byproducts and/or other impurities on the top surface 304 of the source/drain contact structure 126. The wet cleaning operation may be performed to clean the top surface 304 of the source/drain contact structure 126 in preparation for the wet etch operation, and may therefore be referred to as a precleaning operation or prewetting operation.

As the second etching operation is performed to remove the impurity layer 306, in some implementations, an oxidizing agent may be applied to oxidize the upper surface portion of source/drain contact structure 126 (e.g., the metal part containing the impurities), causing that portion to be oxidized and then dissolved and washed away, thereby achieving the effect of removing the impurity layer 306.

An oxidizer (e.g., a wet etchant such as an oxygen (O)-containing wet etchant) may be provided into the recess 302 to etch the top surface 304 of the source/drain contact structure 126 to remove the impurity layer 306 from the top surface 304. The oxygen-containing wet etchant may include an ozone (O₃)-based wet etchant such as ozonated deionized water (DIO₃). The concentration of ozone (O₃) in the ozonated wet etchant may be included in a range of approximately 6 parts per million to approximately 50 parts per million to achieve a sufficiently high etch rate for the impurity layer 306. However, other values and ranges are within the scope of the present disclosure.

In some implementations, two or more different etch rates may occur during the wet etch process since the impurity layer 306 includes a carbon (C) residue, a tungsten nitride (WN) byproduct, and/or a tungsten oxide (WOₓ) byproduct. For example, the tungsten oxide (WOₓ) may only appear on topmost surface and may have a first etch rate, and the carbon and/or the WN may appear in a deeper portion of the impurity layer 306 and may have a second etch rate.

In some implementations, the wet etch operation may be performed at a temperature in the processing chamber that is included in a range of approximately 25 degrees Celsius to approximately 100 degrees to achieve a sufficiently high etch rate for the impurity layer 306.

However, other values and ranges are within the scope of the present disclosure. In some implementations, the wet etch operation may be performed for a time duration of approximately 1 minute to approximately 5 minutes so that the impurity layer 306 is substantially fully removed. However, other values and ranges are within the scope of the present disclosure.

In some implementations, one or more post-cleaning operations are performed to clean the top surface 304 of the source/drain contact structure 126 after the wet etch operation. For example, a first post-clean operation may be performed to remove process byproducts of the wet etch operation such as tungsten oxide (WOₓ). The first post-clean operation may include using deionized water or hot deionized water (HDI) to clean the top surface 304 of the source/drain contact structure 126 by dissolving the tungsten oxide. For example, tungsten oxide, due to the strong acidity of hydrochloric acid, can react with the oxide to form soluble chlorides. However, in some implementations, the first post-clean operation using HDI may be omitted. As another example, a second post-clean operation may be performed after the first post-clean operation, and the second post-clean operation may include using a chelating agent such as hydrochloric acid (HCl). In some implementations, an approximately 50 degree HCl includes mixing HCl into hot deionized water (HIDI), so as to remove metal ions from the surface of the source/drain contact structure 126.

As shown in FIG. 3F, a seed layer 308 of the source/drain interconnect structure 138 may be deposited on the top surface 304 of the source/drain contact structure 126 in the recess 302. The seed layer 308 may be formed as a growth substrate for the bulk material of the source/drain interconnect structure 138. The seed layer 308 may promote a particular direction of material growth, and may promote adhesion of the material of the source/drain interconnect structure 138 to the surfaces of the recess 302.

In some implementations, the seed layer 308 includes the same metal material that is to be deposited for the source/drain interconnect structure 138. For example, the source/drain interconnect structure 138 may be subsequently formed of a metal material such as tungsten (W), and the seed layer 308 may also include tungsten. In some implementations, the seed layer 308 includes a different metal material than the metal material that is to be deposited for the source/drain interconnect structure 138.

A deposition tool may be used to deposit the material of the seed layer 308 using a deposition technique such as CVD, PVD, ALD, and/or another suitable deposition technique. In some implementations, PVD may be used to deposit the seed layer 308. In these implementations, the seed layer 308 is substantially fluorine-free and substantially chlorine-free. This is because PVD is a physical process in which the material of the seed layer 308 is deposited by physical bombardment (e.g., sputtering) of the material of the seed layer 308 from a material target. The use of PVD for depositing the tungsten material of the seed layer 308 may also enable a larger grain size to be achieved in the seed layer 308, which promotes formation of larger grain sizes in the bulk material of the source/drain interconnect structure 138 that is to be subsequently deposited. The larger grain size provides for lower electrical resistance in the source/drain interconnect structure 138.

As shown in FIG. 3G, the bulk material of the source/drain interconnect structure 138 may be deposited on the seed layer 308 in the recess 302 so that the source/drain interconnect structure 138 grows in a bottom-up manner in the recess 302 from the seed layer 308. The bottom-up growth of the source/drain interconnect structure 138 in the recess 302 (e.g., as opposed to lateral growth from the sidewalls of the recess 302) minimizes the likelihood of the formation of voids in the source/drain interconnect structure 138, and therefore the source/drain interconnect structure 138 may be substantially void free.

A deposition tool may be used to deposit the bulk material of the source/drain interconnect structure 138 using a CVD technique, a PVD technique, an ALD technique, an electroplating technique, and/or another suitable deposition technique. The bulk material of the source/drain interconnect structure 138 may be the same metal material as the seed layer 308, such as tungsten (W) among other examples.

In some implementations, the material of the seed layer 308 and the bulk material of the source/drain interconnect structure 138 are deposited using different deposition techniques. For example, and as described above in connection with FIG. 3F, the material of the seed layer 308 may be deposited using a PVD technique so that the seed layer 308 is substantially fluorine-free and substantially chlorine-free. The bulk material of the source/drain interconnect structure 138 may instead be deposited using a CVD technique or another chemical-based deposition technique to achieve a high step coverage to minimize void formation in the source/drain interconnect structure 138. The CVD technique may involve the use of chemical precursors of the bulk material of the source/drain interconnect structure 138, which may contain fluorine (F) and/or chlorine (CI). Thus, the bulk material of the source/drain interconnect structure 138 may have a greater fluorine concentration and/or a greater chlorine concentration than the seed layer 308 The source/drain interconnect structure 138 may be planarized to remove excess material from the source/drain interconnect structure 138. A planarization tool may be used to perform a planarization operation (e.g., a CMP operation) to planarize the source/drain interconnect structure 138. The planarization operation may result in the top of the source/drain interconnect structure 138 being approximately co-planar with the top of the second ILD layer 130.

As further shown in a close-up view 312 in FIG. 3G, a bottom surface 310 of the source/drain interconnect structure 138 may be recessed in the top surface 304 of the source/drain contact structure 126 because of the wet etch operation that was performed to remove the impurity layer 306. Thus, the interface between the bottom surface 310 of the source/drain interconnect structure 138 and the top surface 304 of the source/drain contact structure 126 may be non-linear and curved. For example, the interface between the bottom surface 310 of the source/drain interconnect structure 138 and the top surface 304 of the source/drain contact structure 126 may be curved upward from the center of the source/drain interconnect structure 138 to a perimeter of the source/drain interconnect structure 138. The interface between the bottom surface 310 of the source/drain interconnect structure 138 and the top surface 304 of the source/drain contact structure 126 may also be substantially free of impurities from the impurity layer 306, including metal nitride impurities of the metal material of the source/drain contact structure 126.

The bottom surface 310 of the source/drain interconnect structure 138 may be lower than the bottom surface of the second ESL 132 in the semiconductor device 100, and may have a curved convex profile. The bottom surface 310 of the source/drain interconnect structure 138 may extend below the bottom surface of the second ESL 132 (and may be recessed within the top surface 304 of the source/drain contact structure 126) to a depth corresponding to the dimension D3.

As indicated above, FIGS. 3A-3G are provided as an example. Other examples may differ from what is described with regard to FIGS. 3A-3G.

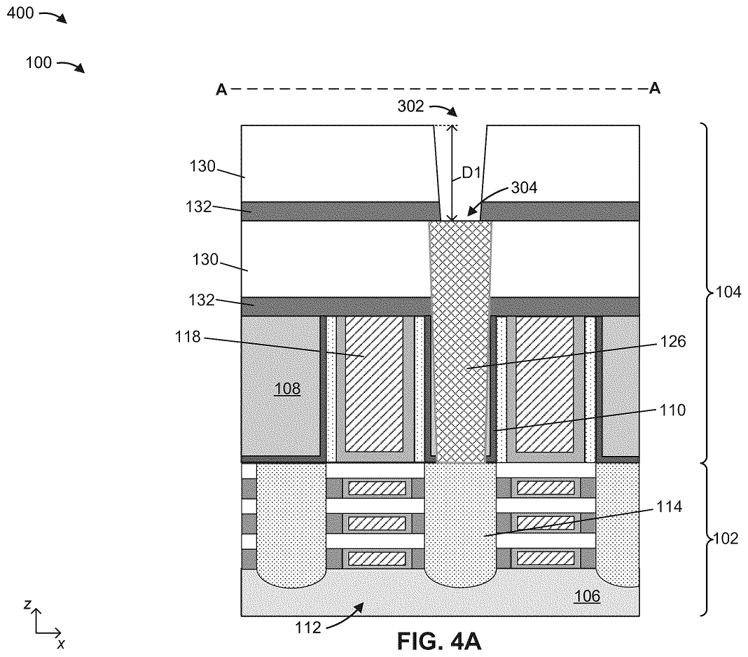

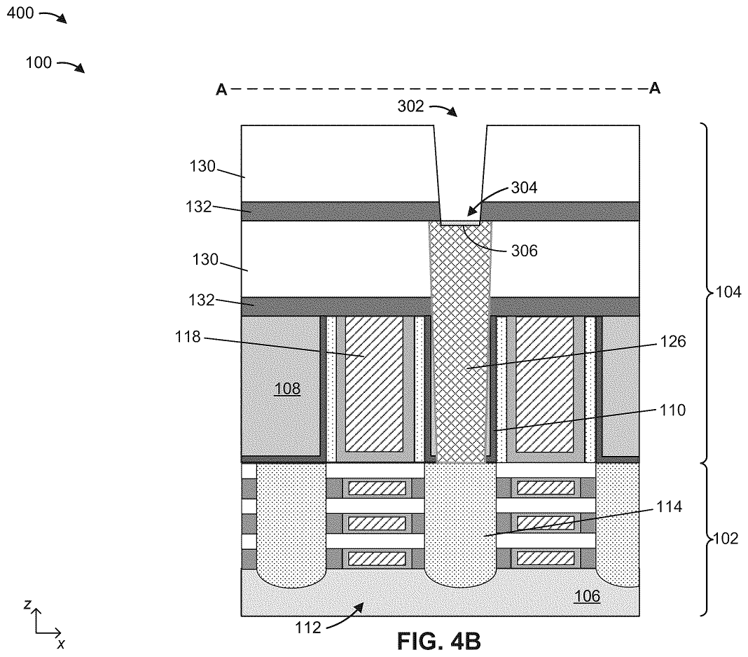

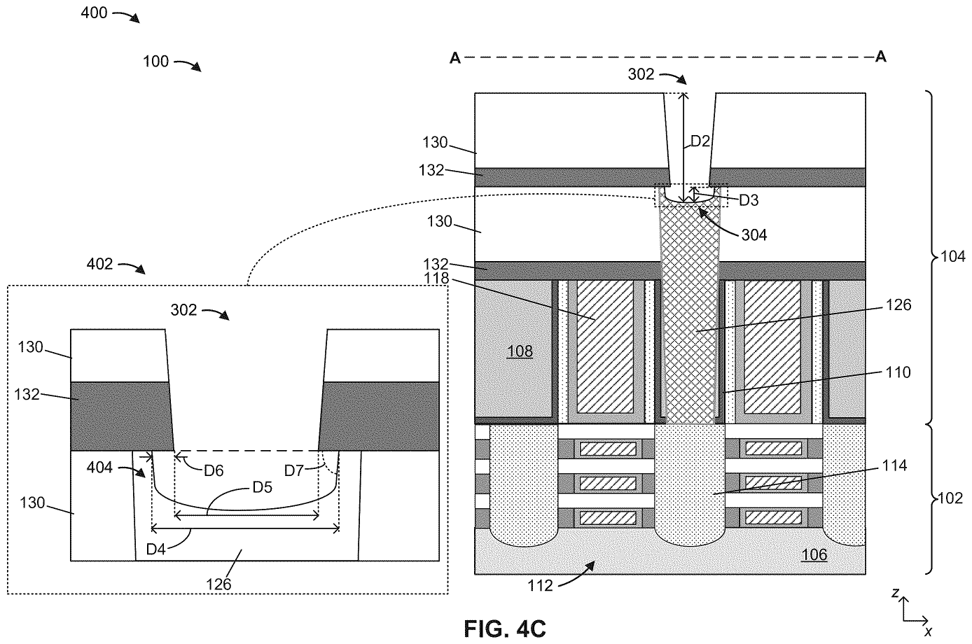

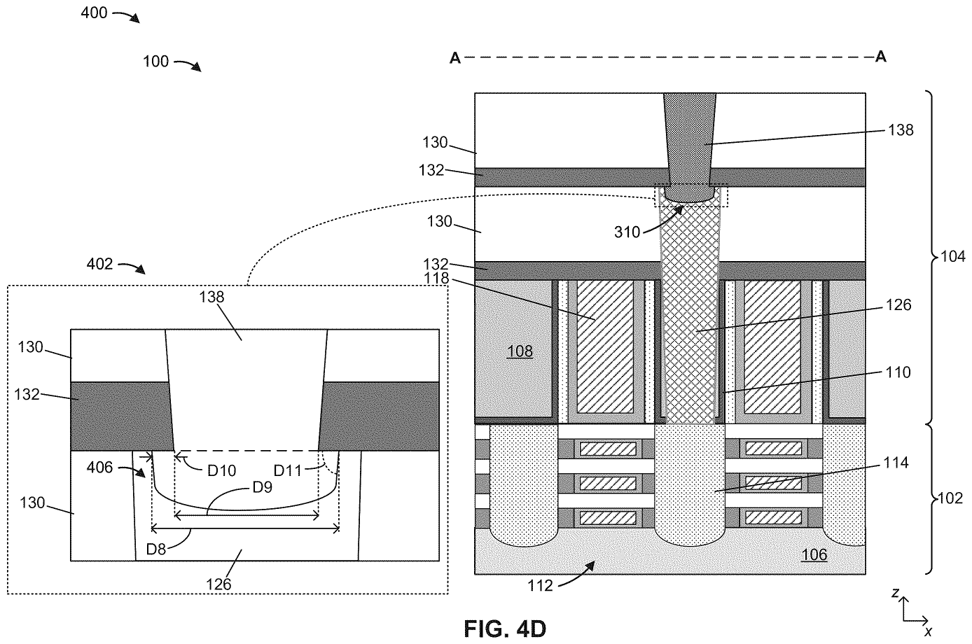

FIGS. 4A-4D are diagrams of an example implementation 400 of forming an interconnect layer 104 (or a portion thereof) of the semiconductor device 100 described herein.

In particular, the example implementation 400 includes an example of forming a source/drain interconnect structure 138 in the interconnect layer 104 (e.g., the back end region or BEOL region) of the semiconductor device 100.

As shown in FIGS. 4A-4D, the example implementation 400 includes a similar combination of operations as the example implementation 300 shown and described in connection with FIGS. 3A-3G. However, and as shown in FIG. 4C, some lateral expansion of the recess 302 occurs within the top surface 304 of the source/drain contact structure 126 during the wet etch operation to remove the impurity layer 306. The lateral expansion may result because of the isotropic etch that occurs from the use of a wet etchant. Thus, the lateral width (indicated in a close-up view 402 in FIG. 4C as a dimension D4) of the portion of the recess 302 in the top surface 304 of the source/drain contact structure 126 under the second ESL 132 may be greater than the lateral width (indicated in the close-up view 402 in FIG. 4C as a dimension D5) of the portion of the recess 302 in the second ESL 132. In some implementations, a ratio of the depth of the recess to the lateral width of the portion of the recess 302 in the second ESL 132 (e.g., D3:D5) may be included in a range of approximately 0.5:1 to approximately 1:1 to ensure full removal of the impurity layer 306. However, other values and ranges are within the scope of the present disclosure.

The amount of lateral expansion in a portion 404 of the recess 302 in the top surface 304 of the source/drain contact structure 126 (in other words, the distance that the recess 302 extends under the second ESL 132-indicated in the close-up view 402 in FIG. 4C as a dimension D6) may be greater than 0 nanometers and up to approximately 10 nanometers.

However, other values and ranges are within the scope of the present disclosure. In some implementations, a ratio of the depth of the recess 302 to the amount of lateral expansion in the portion 404 of the recess 302 (e.g., D3:D6) may be included in a range of approximately 2:1 to approximately 10:1 to ensure full removal of the impurity layer 306. However, other values and ranges are within the scope of the present disclosure.

An angle between the bottom surface of the ESL 132 and a sidewall of the portion 404 of the recess 302 in the top surface 304 of the source/drain contact structure 126 (indicated in the close-up view 402 in FIG. 4C as a dimension D7) may be included in a range of approximately 30 degrees to approximately 90 degrees. However, other values and ranges are within the scope of the present disclosure.

As shown in FIG. 4D, a recessed portion 406 of the source/drain interconnect structure 138 may correspond to the bottom portion of the source/drain interconnect structure 138 that is formed in the portion 404 of the recess 302 that extended into the top surface 304 of the source/drain contact structure 126. Because of the lateral expansion of the recess 302 within the top surface 304 of the source/drain contact structure 126 during the wet etch operation to remove the impurity layer 306, the recessed portion 406 of the source/drain interconnect structure 138 may extend laterally under the second ESL 132. Thus, the lateral width (indicated in the close-up view 402 in FIG. 4D as a dimension D8) of the recessed portion 406 of the source/drain interconnect structure 138 in the top surface 304 of the source/drain contact structure 126 under the second ESL 132 may be greater than the lateral width (indicated in the close-up view 402 in FIG. 4C as a dimension D9) of the recessed portion 406 of the source/drain interconnect structure 138 at the depth of the second ESL 132. The recessed portion 406 may have higher nitrogen concentration than that of the other portions of the source/drain interconnect structure 138 because the recessed portion 406 may contain nitrogen from the ESL 132, whereas the other portions that contained nitrogen have been etched away.

The amount of lateral extension in the recessed portion 406 of the source/drain interconnect structure 138 (in other words, the distance that the recessed portion 406 extends under the second ESL 132-indicated in the close-up view 402 in FIG. 4D as a dimension D10) may be greater than 0 nanometers and up to approximately 10 nanometers. However, other values and ranges are within the scope of the present disclosure. An angle between the bottom surface of the ESL 132 and a sidewall of the recessed portion 406 of the source/drain interconnect structure 138 (indicated in the close-up view 402 in FIG. 4D as a dimension D11) may be included in a range of approximately 30 degrees to approximately 90 degrees. However, other values and ranges are within the scope of the present disclosure.

As indicated above, FIGS. 4A-4D are provided as an example. Other examples may differ from what is described with regard to FIGS. 4A-4D.

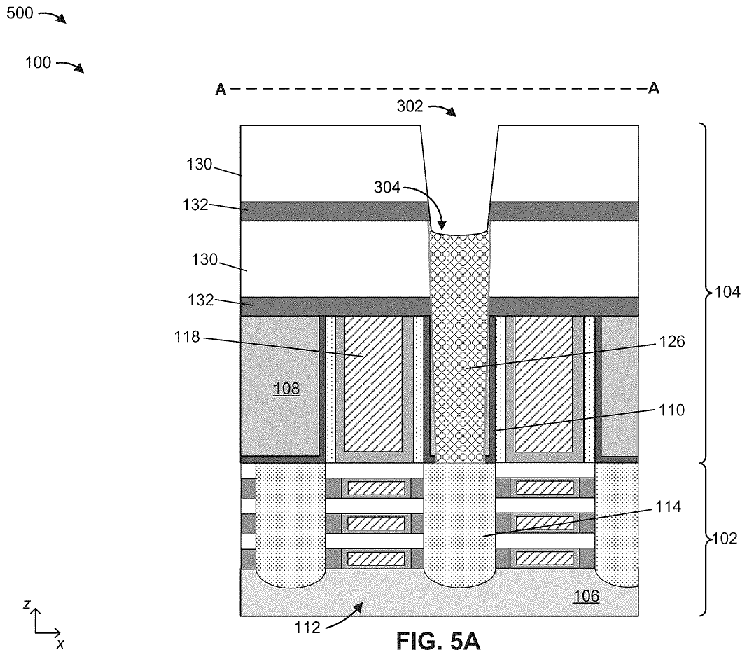

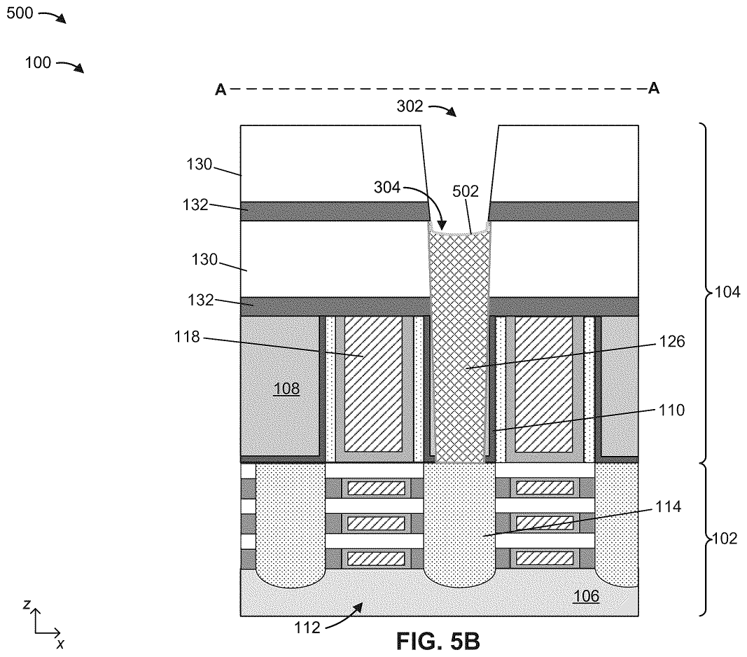

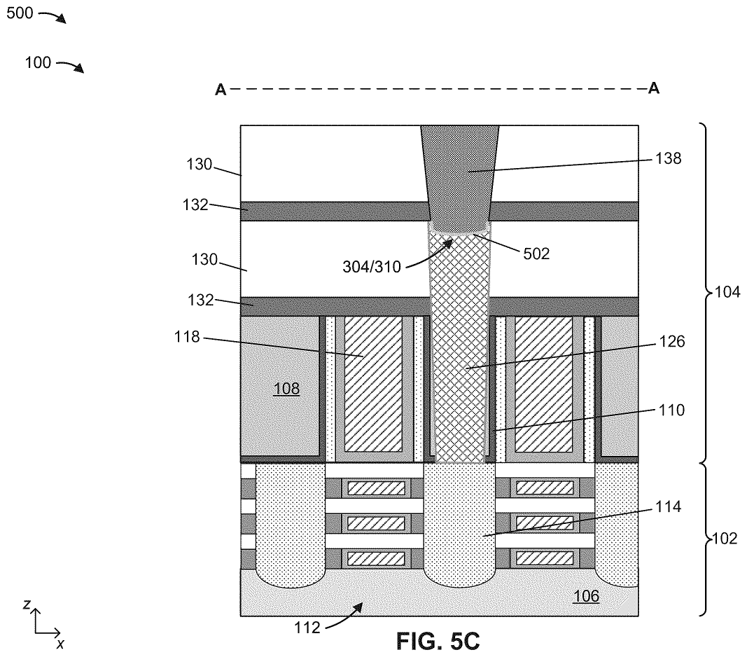

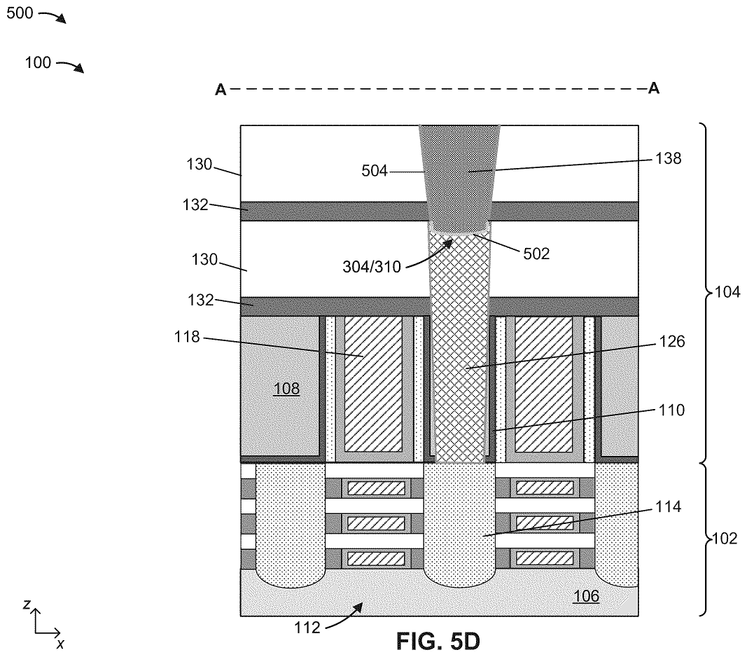

FIGS. 5A-5D are diagrams of an example implementation 500 of forming an interconnect layer 104 (or a portion thereof) of the semiconductor device 100 described herein. In particular, the example implementation 500 includes an example of forming a source/drain interconnect structure 138 in the interconnect layer 104 (e.g., the back end region or BEOL region) of the semiconductor device 100.

As shown in FIGS. 5A-5D, the example implementation 500 includes a similar combination of operations as the example implementation 300 shown and described in connection with FIGS. 3A-3G. However, and as shown in FIG. 5B, a liner 502 may be formed on the top surface 304 of the source/drain contact structure 126 prior to formation of the source/drain interconnect structure 138 in the recess 302. Thus, the liner 502 may be located below the second ESL 132. The liner 502 may include a tungsten (W) liner and/or another type of liner. The liner 502 may be deposited by ALD, CVD, PVD, and/or another suitable deposition technique.

As shown in FIG. 5C, the material of the source/drain interconnect structure 138 may be deposited on the liner 502 in the recess 302. The liner 502 may be located between the bottom surface 310 of the source/drain interconnect structure 138 and the top surface 304 of the source/drain contact structure 126.

FIG. 5D illustrates an alternative implementation in which one or more liners 504 may be included between the sidewalls of the source/drain interconnect structure 138 and the ILD layer 130 and/or the ESL 132. The liner(s) 504 may include barrier liners, adhesion liners, and/or another type of liner, and may include materials such as tantalum nitride (TaN) and/or titanium nitride (TiN), among other examples.

As indicated above, FIGS. 5A-5D are provided as an example. Other examples may differ from what is described with regard to FIGS. 5A-5D.

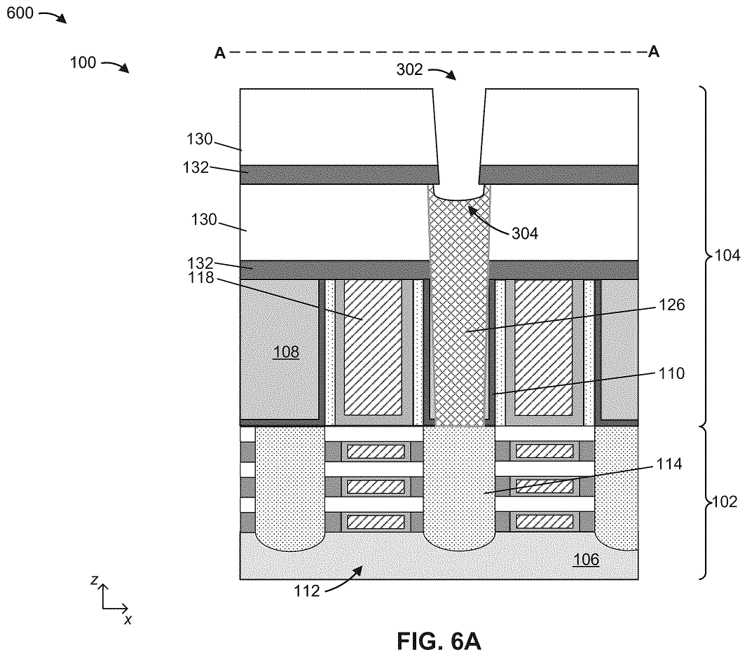

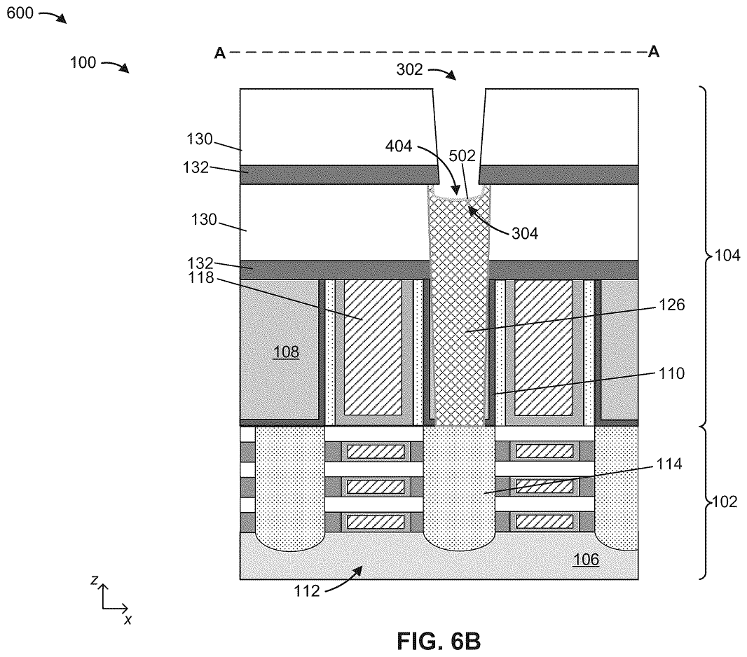

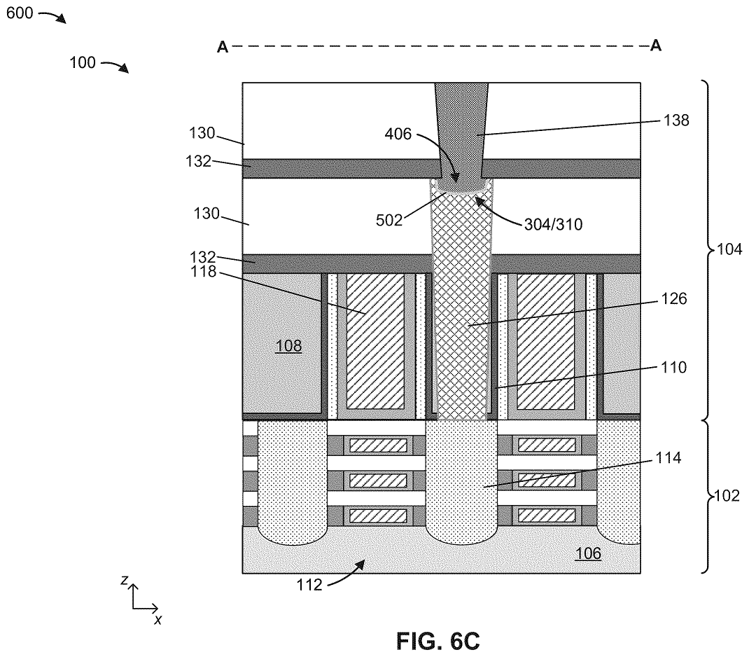

FIGS. 6A-6C are diagrams of an example implementation 600 of forming an interconnect layer 104 (or a portion thereof) of the semiconductor device 100 described herein. In particular, the example implementation 600 includes an example of forming a source/drain interconnect structure 138 in the interconnect layer 104 (e.g., the back end region or BEOL region) of the semiconductor device 100.

As shown in FIGS. 6A-6C, the example implementation 500 includes a similar combination of operations as the example implementation 400 shown and described in connection with FIGS. 4A-4D. However, and as shown in FIG. 6B, a liner 502 may be formed on the top surface 304 of the source/drain contact structure 126 in the portion 404 of the recess 302 that is below the second ESL 132. Thus, the liner 502 may be located below the second ESL 132. The liner 502 may include a tungsten (W) liner and/or another type of liner. The liner 502 may be deposited by ALD, CVD, PVD, and/or another suitable deposition technique.

As shown in FIG. 6C, the material of the source/drain interconnect structure 138 may be deposited on the liner 502 in the recess 302. The liner 502 may be located between the bottom surface 310 of the source/drain interconnect structure 138 and the top surface 304 of the source/drain contact structure 126, and may extend along the surfaces of the recessed portion 406 of the source/drain interconnect structure 138.

As indicated above, FIGS. 6A-6C are provided as an example. Other examples may differ from what is described with regard to FIGS. 6A-6C.

FIGS. 7A-7F are diagrams of an example implementation 700 of forming an interconnect layer 104 (or a portion thereof) of the semiconductor device 100 described herein.

In particular, the example implementation 700 includes an example of forming a gate interconnect structure 140 in the interconnect layer 104 (e.g., the back end region or BEOL region) of the semiconductor device 100.

In some implementations, one or more of the semiconductor processing operations described in connection with FIGS. 7A-7F may be performed as part of the process of forming the semiconductor device 100 illustrated and described in connection with FIGS. 2A-2E. For example, one or more of the semiconductor processing operations described in connection with FIGS. 7A-7F may be performed as part of the process of forming the interconnect layer 104 shown in FIG. 2E. In some implementations, one or more of the semiconductor processing operations described in connection with FIGS. 7A-7F may be performed after the operations described in connection with FIGS. 3A-3G, 4A-4D, 5A-5D, and/or 6A-6C. In other words, the gate interconnect structure 140 may be formed after the source/drain interconnect structure 138. Alternatively, the gate interconnect structure 140 may be formed prior to formation of the source/drain interconnect structure 138.

One or more of the semiconductor processing operations described in connection with FIGS. 7A-7F may be performed using one or more semiconductor processing tools, such as a deposition tool, an exposure tool, a developer tool, an etch tool, a planarization tool, an ion implantation tool, a wafer/die transport tool, and/or another type of semiconductor processing tool.

As shown in FIG. 7A, the interconnect layer 104 of the semiconductor device 100 is formed above the dielectric layer 108 of the device layer 102. Forming the interconnect layer 104 may include forming the first ESL 132, the first ILD layer 130, the second ESL 132, and/or the second ILD layer 130 over and/or on the dielectric layer 108. In some implementations, one or more source/drain contact structures 126 may be formed in and/or through the first ILD layer 130, the first ESL 132, and the dielectric layer 108 to one or more source/drain regions 114.

As shown in FIG. 7B, a recess 702 may be formed over a gate structure 118 of an integrated circuit device 112 to expose a top surface 704 of the gate structure 118 through the second ILD layer 130, the second ESL 132, the first ILD layer 130, and the first ESL 132. In some implementations, a pattern in a photoresist layer is used to etch the second ILD layer 130, the second ESL 132, the first ILD layer 130, and/or the first ESL 132 to form the recess 302. In these implementations, a deposition tool may be used to form the photoresist layer on the second ILD layer 130 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern.

An etch tool may be used to etch the second ILD layer 130, the second ESL 132, the first ILD layer 130, and/or the first ESL 132 based on the pattern to form the recess 702 to a first depth indicated in FIG. 7B as a dimension D12. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recess 302 based on a pattern.

As shown in FIG. 7C, an impurity layer 706 may form in the top surface 704 of the gate structure 118. The impurity layer 706 may include a carbon (C) residue, a tungsten nitride (WN) byproduct, a tungsten oxide (WOₓ) byproduct, and/or another type of impurity that is driven into the top surface 704 as opposed to a native oxide that grows on top of the top surface 704.

The impurity layer 706 may increase the contact resistance between the gate structure 118 and the gate interconnect structure 140 that is to be formed in the recess 702, and/or may increase the likelihood of corrosion of the metal material of the gate interconnect structure 140.

Accordingly, and as shown in FIG. 7D, a wet cleaning operation and a wet etch operation may be performed to etch the top surface 704 to remove the impurity layer 706. The removal of the impurity layer 706 results in the top surface 704 of the gate structure 118 being concave and recessed below the bottom surface of the first ESL 132. Thus, the depth of the recess 702 may be increased from the first depth (dimension D12) to a second depth (indicated in FIG. 7D as a dimension D13) that is greater than the first depth. In some implementations, the depth of the concavity or recess in the top surface 704 of the gate structure 118 (indicated in FIG. 7D as a dimension D14) may be included in a range of approximately 1 nanometer to approximately 20 nanometers to achieve a high likelihood that the impurity layer 706 is fully removed. However, other values and ranges are within the scope of the present disclosure.

The wet cleaning operation and the wet etch operation may include the use of an etch tool. The semiconductor device 100 is placed in a processing chamber of the etch tool. For the wet cleaning operation, a wet cleaning agent such as isopropyl alcohol (IPA) may be provided into the recess 702 to clean process byproducts and/or other impurities on the top surface 704 of the gate structure 118. The wet cleaning operation may be performed to clean the top surface 704 of the gate structure 118 in preparation for the wet etch operation, and may therefore be referred to as a precleaning operation or prewetting operation.

For the wet etch operation, a wet etchant such as an oxygen (O)-containing wet etchant may be provided into the recess 702 to etch the top surface 704 of the gate structure 118 to remove the impurity layer 706 from the top surface 704. The oxygen-containing wet etchant may include an ozone (O₃)-based wet etchant such as ozonated deionized water (DIO₃). The concentration of ozone (O₃) in the ozonated wet etchant may be included in a range of approximately 6 parts per million to approximately 50 parts per million to achieve a sufficiently high etch rate for the impurity layer 706. However, other values and ranges are within the scope of the present disclosure.

In some implementations, the wet etch operation may be performed at a temperature in the processing chamber that is included in a range of approximately 25 degrees Celsius to approximately 100 degrees to achieve a sufficiently high etch rate for the impurity layer 706.

However, other values and ranges are within the scope of the present disclosure. In some implementations, the wet etch operation may be performed for a time duration of approximately 1 minute to approximately 5 minutes so that the impurity layer 706 is substantially fully removed. However, other values and ranges are within the scope of the present disclosure.

In some implementations, one or more post-cleaning operations are performed to clean the top surface 704 of the gate structure 118 after the wet etch operation. For example, a first post-clean operation may be performed to remove process byproducts of the wet etch operation such as tungsten oxide (WOₓ). The first post-clean operation may include using deionized water or hot deionized water (HDI) to clean the top surface 704 of the gate structure 118. However, in some implementations, the first post-clean operation using HDI may be omitted. As another example, a second post-clean operation may be performed after the first post-clean operation, and the second post-clean operation may include using a chelating agent such as hydrochloric acid (HCl).

As shown in FIG. 7E, a liner 708 may be formed on the surfaces of the recess 702. For example the material of the liner 708 may be deposited on the sidewalls and the bottom surface of the recess 702 such that the liner 708 is deposited in the concave top surface of the gate structure 118. A deposition tool may be used to deposit the material of the liner 708 using a deposition technique such as CVD, PVD, ALD, and/or another suitable deposition technique.

As shown in FIG. 7F, the material of the gate interconnect structure 140 may be deposited on the liner 708 in the recess 702 so that the gate interconnect structure 140 is formed on the gate structure 118. A deposition tool may be used to deposit the material of the gate interconnect structure 140 using a CVD technique, a PVD technique, an ALD technique, an electroplating technique, and/or another suitable deposition technique. The material of the gate interconnect structure 140 may be the same metal material as the liner 708, such as tungsten (W) among other examples. Alternatively, the material of the gate interconnect structure 140 may be different than the material of the liner 708.

The gate interconnect structure 140 may be planarized to remove excess material from the gate interconnect structure 140. A planarization tool may be used to perform a planarization operation (e.g., a CMP operation) to planarize the gate interconnect structure 140. The planarization operation may result in the top of the gate interconnect structure 140 being approximately co-planar with the top of the second ILD layer 130.

A bottom surface 710 of the gate interconnect structure 140 may be recessed in the top surface 704 of the gate structure 118 because of the wet etch operation that was performed to remove the impurity layer 706. Thus, the interface between the bottom surface 710 of the gate interconnect structure 140 and the top surface 704 of the gate structure 118 may be non-linear and curved. For example, the interface between the bottom surface 710 of the gate interconnect structure 140 and the top surface 704 of the gate structure 118 may be curved upward from the center of the gate interconnect structure 140 to a perimeter of the gate interconnect structure 140. The interface between the bottom surface 710 of the gate interconnect structure 140 and the top surface 704 of the gate structure 118 may also be substantially free of impurities from the impurity layer 706, including metal nitride impurities of the metal material of the gate structure 118 The bottom surface 710 of the gate interconnect structure 140 may be lower than the bottom surface of the first ESL 132 in the semiconductor device 100, and may have a curved convex profile. The bottom surface 710 of the gate interconnect structure 140 may extend below the bottom surface of the first ESL 132 (and may be recessed within the top surface 704 of the gate structure 118) to a depth corresponding to the dimension D14.

As indicated above, FIGS. 7A-7F are provided as an example. Other examples may differ from what is described with regard to FIGS. 7A-7F.

FIGS. 8A-8F are diagrams of an example implementation 800 of forming an interconnect layer 104 (or a portion thereof) of the semiconductor device 100 described herein.

In particular, the example implementation 800 includes an example of forming a merged interconnect structure 142 in the interconnect layer 104 (e.g., the back end region or BEOL region) of the semiconductor device 100.

In some implementations, one or more of the semiconductor processing operations described in connection with FIGS. 8A-8F may be performed as part of the process of forming the semiconductor device 100 illustrated and described in connection with FIGS. 2A-2E. For example, one or more of the semiconductor processing operations described in connection with FIGS. 8A-8F may be performed as part of the process of forming the interconnect layer 104 shown in FIG. 2E.

In some implementations, one or more of the semiconductor processing operations described in connection with FIGS. 8A-8F may be performed after the operations described in connection with FIGS. 3A-3G, 4A-4D, 5A-5D, and/or 6A-6C. In other words, the merged interconnect structure 142 may be formed after the source/drain interconnect structure 138.

Alternatively, the merged interconnect structure 142 may be formed prior to formation of the source/drain interconnect structure 138.

In some implementations, one or more of the semiconductor processing operations described in connection with FIGS. 8A-8F may be performed after the operations described in connection with FIGS. 7A-7F. In other words, the merged interconnect structure 142 may be formed after the gate interconnect structure 140. In some implementations, the merged interconnect structure 142 may be formed prior to formation of the gate interconnect structure 140.

In some implementations, one or more of the semiconductor processing operations described in connection with FIGS. 8A-8F may be performed concurrently with one or more operations described in connection with FIGS. 7A-7F. In other words, the operations described in connection with FIG. 8B for forming a recess 802 for the merged interconnect structure 142, and the operations described in connection with FIG. 7B for forming the recess 702 for the gate interconnect structure 140, may be performed as part of unified process. Similarly, the operations described in connection with FIG. 8D for performing the cleaning and wet etch operations for the recess 802 for merged interconnect structure 142, and the operations described in connection with FIG. 7D for performing the cleaning and wet etch operations for the recess 702 for the gate interconnect structure 140, may be performed as part of unified process.

Similarly, the operations described in connection with FIGS. 8E and 8F for depositing the material of the merged interconnect structure 142, and the operations described in connection with FIGS. 7E and 7F for depositing the material of the gate interconnect structure 140, may be performed as part of unified process.

One or more of the semiconductor processing operations described in connection with FIGS. 8A-8F may be performed using one or more semiconductor processing tools, such as a deposition tool, an exposure tool, a developer tool, an etch tool, a planarization tool, an ion implantation tool, a wafer/die transport tool, and/or another type of semiconductor processing tool.

As shown in FIG. 8A, the interconnect layer 104 of the semiconductor device 100 is formed above the dielectric layer 108 of the device layer 102. Forming the interconnect layer 104 may include forming the first ESL 132, the first ILD layer 130, the second ESL 132, and/or the second ILD layer 130 over and/or on the dielectric layer 108. In some implementations, one or more source/drain contact structures 126 may be formed in and/or through the first ILD layer 130, the first ESL 132, and the dielectric layer 108 to one or more source/drain regions 114.

As shown in FIG. 8B, a recess 802 may be formed over a gate structure 118 of an integrated circuit device 112 and over a source/drain contact structure 126 of an integrated circuit device 112. In some implementations, the gate structure 118 and the source/drain contact structure 126 may be included in the same integrated circuit device 112. For example, the gate structure 118 and the source/drain contact structure 126 may be included in a transistor structure formed in the device layer 102. In these implementations, the merged interconnect structure 142 may be formed to electrically couple the gate structure 118 and the source/drain contact structure 126 of the transistor structure. In some implementations, the gate structure 118 and the source/drain contact structure 126 may be included in separate integrated circuit devices 112.

For example, the gate structure 118 may be included in a first transistor structure formed in the device layer 102, and the source/drain contact structure 126 may be included in a second transistor structure formed in the device layer 102. In these implementations, the merged interconnect structure 142 may be formed to electrically couple the gate structure 118 of the first transistor to the source/drain contact structure 126 of the second transistor structure.

As shown in FIG. 8D, the recess 802 may include a first portion 804 that is formed to a first depth (indicated in in FIG. 8B as a dimension D15) and a second portion 806 that is formed to a second depth (indicated in in FIG. 8B as a dimension D16) that is greater than the first depth (e.g., D16>D15). The first portion 804 may be formed over the source/drain contact structure 126 such that a top surface 808 of the source/drain contact structure 126 is exposed in the recess 802. The second portion 806 may be formed over the gate structure 118 such that a top surface 810 of the gate structure 118 is exposed in the recess 802. The first portion 804 of the recess 802 may also extend over a portion 812 of the first ILD layer 130 laterally between the gate structure 118 and the source/drain contact structure 126. Thus, the bottom surface of the recess 802 may have a stepped profile that steps down to the top surface 810 of the gate structure 118 in the second portion 806 from the portion 812 of the first ILD layer 130 and the top surface 808 of the source/drain contact structure 126 in the first portion 804.

In some implementations, a pattern in a photoresist layer is used to etch the second ILD layer 130, the second ESL 132, the first ILD layer 130, and/or the first ESL 132 to form the recess 802. In these implementations, a deposition tool may be used to form the photoresist layer on the second ILD layer 130 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern.

An etch tool may be used to etch the second ILD layer 130, the second ESL 132, the first ILD layer 130, and/or the first ESL 132 based on the pattern to form the recess 802. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recess 802 based on a pattern.

As shown in FIG. 8C, an impurity layer 814 may form in the top surface 808 of the gate structure 118, and an impurity layer 816 may form in the top surface 810 of the gate structure 118. The impurity layer 814 may include a carbon (C) residue, a tungsten nitride (WN) byproduct, a tungsten oxide (WOₓ) byproduct, and/or another type of impurity that is driven into the top surface 808 as opposed to a native oxide that grows on top of the top surface 808. The impurity layer 816 may include a carbon (C) residue, a tungsten nitride (WN) byproduct, a tungsten oxide (WOₓ) byproduct, and/or another type of impurity that is driven into the top surface 810 as opposed to a native oxide that grows on top of the top surface 810.

As shown in FIG. 8D, a wet cleaning operation and a wet etch operation may be performed to etch the top surfaces 808 and 810 to respectively remove the impurity layers 814 and 816. The removal of the impurity layer 814 results in the top surface 808 of the source/drain contact structure 126 being concave and recessed below the bottom surface of the second ESL 132. Thus, the depth of the first portion 804 of the recess 802 over the source/drain contact structure 126 may be increased from the first depth (dimension D15) to a third depth (indicated in FIG. 8D as a dimension D17) that is greater than the first depth. The removal of the impurity layer 816 results in the top surface 810 of the gate structure 118 being concave and recessed below the bottom surface of the first ESL 132. Thus, the depth of the second portion 806 of the recess 802 over the gate structure 118 may be increased from the second depth (dimension D16) to a fourth depth (indicated in FIG. 8D as a dimension D18) that is greater than the second depth. The portion 812 of the first ILD layer 130 between the gate structure 118 and the source/drain contact structure 126 may be substantially unetched and may remain at the first depth (indicated in FIG. 8D as the dimension D15).

In some implementations, the depth of the concavity or recess in the top surface 808 of the source/drain contact structure 126 (indicated in FIG. 8D as a dimension D19) may be included in a range of approximately 1 nanometer to approximately 20 nanometers to achieve a high likelihood that the impurity layer 814 is fully removed. However, other values and ranges are within the scope of the present disclosure. In some implementations, the depth of the concavity or recess in the top surface 810 of the gate structure 118 (indicated in FIG. 8D as a dimension D20) may be included in a range of approximately 1 nanometer to approximately 20 nanometers to achieve a high likelihood that the impurity layer 816 is fully removed. However, other values and ranges are within the scope of the present disclosure.

The wet cleaning operation and the wet etch operation may include the use of an etch tool. The semiconductor device 100 is placed in a processing chamber of the etch tool. For the wet cleaning operation, a wet cleaning agent such as isopropyl alcohol (IPA) may be provided into the recess 802 to clean process byproducts and/or other impurities on the top surface 808 of the source/drain contact structure 126 and on the top surface 810 of the gate structure 118. The wet cleaning operation may be performed to clean the top surface 808 of the source/drain contact structure 126 and the top surface 810 of the gate structure 118 in preparation for the wet etch operation, and may therefore be referred to as a precleaning operation or prewetting operation.

For the wet etch operation, a wet etchant such as an oxygen (O)-containing wet etchant may be provided into the recess 802 to etch the top surface 808 of the source/drain contact structure 126 and the top surface 810 of the gate structure 118 to remove the impurity layer 814 from the top surface 808 and the impurity layer 816 from the top surface 810. The oxygen-containing wet etchant may include an ozone (O₃)-based wet etchant such as ozonated deionized water (DIO₃). The concentration of ozone (O₃) in the ozonated wet etchant may be included in a range of approximately 6 parts per million to approximately 50 parts per million to achieve a sufficiently high etch rate for the impurity layers 814 and 816. However, other values and ranges are within the scope of the present disclosure.

In some implementations, the wet etch operation may be performed at a temperature in the processing chamber that is included in a range of approximately 25 degrees Celsius to approximately 100 degrees to achieve a sufficiently high etch rate for the impurity layers 814 and 816. However, other values and ranges are within the scope of the present disclosure. In some implementations, the wet etch operation may be performed for a time duration of approximately 1 minute to approximately 5 minutes so that the impurity layers 814 and 816 are substantially fully removed. However, other values and ranges are within the scope of the present disclosure.

In some implementations, one or more post-cleaning operations are performed to clean the top surfaces 808 and 810 after the wet etch operation. For example, a first post-clean operation may be performed to remove process byproducts of the wet etch operation such as tungsten oxide (WOₓ). The first post-clean operation may include using deionized water or hot deionized water (HDI) to clean top surfaces 808 and 810. However, in some implementations, the first post-clean operation using HDI may be omitted. As another example, a second post-clean operation may be performed after the first post-clean operation, and the second post-clean operation may include using a chelating agent such as hydrochloric acid (HCl).

As shown in FIG. 8E, a liner 818 may be formed on the surfaces of the recess 802. For example the material of the liner 818 may be deposited on the sidewalls and the bottom surface of the recess 802 such that the liner 818 is deposited in the concave top surface of the source/drain contact structure 126 and in the concave top surface of the gate structure 118. A deposition tool may be used to deposit the material of the liner 818 using a deposition technique such as CVD, PVD, ALD, and/or another suitable deposition technique.

As shown in FIG. 8F, the material of the merged interconnect structure 142 may be deposited on the liner 818 in the recess 802 so that the merged interconnect structure 142 is formed on the source/drain contact structure 126 and on the gate structure 118. A deposition tool may be used to deposit the material of the merged interconnect structure 142 using a CVD technique, a PVD technique, an ALD technique, an electroplating technique, and/or another suitable deposition technique. The material of the merged interconnect structure 142 may be the same metal material as the liner 818, such as tungsten (W) among other examples. Alternatively, the material of the merged interconnect structure 142 may be different than the material of the liner 818.

In some implementations, the interconnect structure 142 is formed in a sequence of PVD and then CVD. PVD may be used to form a flat or smooth base firstly, so as to avoid formation of a seam in a subsequent CVD process that might otherwise occur due to a non-flat surface. CVD process is also relatively low-cost.

The merged interconnect structure 142 may be planarized to remove excess material from the gate interconnect structure 140. A planarization tool may be used to perform a planarization operation (e.g., a CMP operation) to planarize the merged interconnect structure 142. The planarization operation may result in the top of the merged interconnect structure 142 being approximately co-planar with the top of the second ILD layer 130.

A bottom surface 820 of the merged interconnect structure 142 may be recessed in the top surface 808 of the source/drain contact structure 126 because of the wet etch operation that was performed to remove the impurity layer 814. Thus, the interface between the bottom surface 822 of the merged interconnect structure 142 and the top surface of the gate structure 118 may be non-linear and curved. The interface between the bottom surface 820 of the merged interconnect structure 142 and the top surface 808 of the source/drain contact structure 126 may also be substantially free of impurities from the impurity layer 814, including metal nitride impurities of the metal material of the source/drain contact structure 126. The bottom surface 820 of the merged interconnect structure 142 may extend below the bottom surface of the second ESL 132 (and may be recessed within the top surface of the source/drain contact structure 126) to a depth corresponding to the dimension D19.

A bottom surface 822 of the merged interconnect structure 142 may be recessed in the top surface 810 of the gate structure 118 because of the wet etch operation that was performed to remove the impurity layer 816. Thus, the interface between the bottom surface 822 of the merged interconnect structure 142 and the top surface of the source/drain contact structure 126 may be non-linear and curved. The interface between the bottom surface 822 of the merged interconnect structure 142 and the top surface 810 of the gate structure 118 may also be substantially free of impurities from the impurity layer 816, including metal nitride impurities of the metal material of the gate structure 118. The bottom surface 822 of the merged interconnect structure 142 may extend below the bottom surface of the first ESL 132 (and may be recessed within the top surface of the gate structure 118) to a depth corresponding to the dimension D20.

A bottom surface 824 of the merged interconnect structure 142 over the portion of the first ILD layer 130 between the gate structure 118 and the source/drain contact structure 126 may be higher than the bottom surface 820 recessed in the top surface of the source/drain contact structure 126, and may be higher than the bottom surface 822 recessed in the top surface of the gate structure 118.

As indicated above, FIGS. 8A-8F are provided as an example. Other examples may differ from what is described with regard to FIGS. 8A-8F.

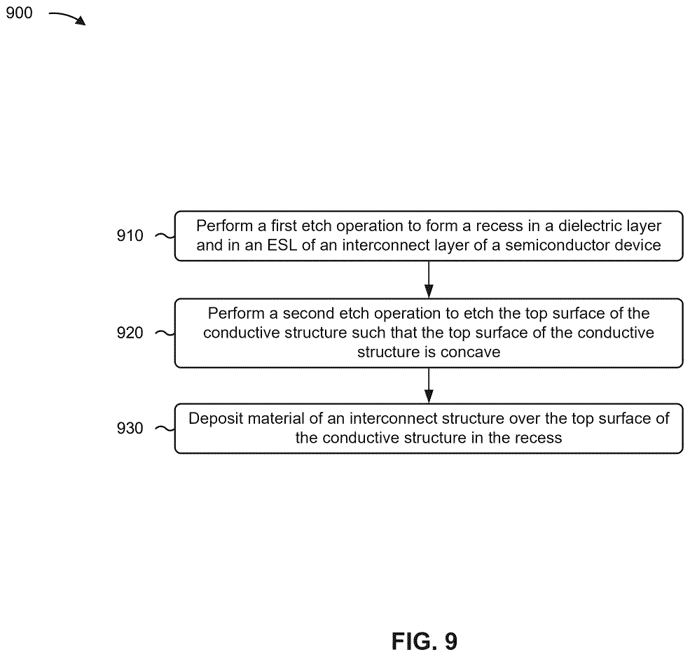

FIG. 9 is a flowchart of an example process 900 associated with forming a semiconductor device described herein. In some implementations, one or more process blocks of FIG. 9 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 9, process 900 may include performing a first etch operation to form a recess in a dielectric layer and in an ESL of an interconnect layer of a semiconductor device (block 910). For example, one or more semiconductor processing tools may be used to perform a first etch operation to form a recess (e.g., a recess 302, a recess 702, a recess 802) in a dielectric layer (e.g., an ILD layer 130) and in an ESL (e.g., an ESL 132) of an interconnect layer (e.g., an interconnect layer 104) of a semiconductor device (e.g., a semiconductor device 100), as described herein. In some implementations, the dielectric layer is above the ESL. In some implementations, the ESL is above a conductive structure (e.g., a gate structure 118, a source/drain contact structure 126) of an integrated circuit device in a device layer (e.g., a device layer 102) of the semiconductor device. In some implementations, a top surface (e.g., a top surface 304, a top surface 704, a top surface 808, a top surface 810) of the conductive structure is exposed in the recess.

As further shown in FIG. 9, process 900 may include performing a second etch operation to etch the top surface of the conductive structure such that the top surface of the conductive structure is concave (block 920). For example, one or more semiconductor processing tools may be used to perform a second etch operation to etch the top surface of the conductive structure such that the top surface of the conductive structure is concave, as described herein.

As further shown in FIG. 9, process 900 may include depositing material of an interconnect structure over the top surface of the conductive structure in the recess (block 930).

For example, one or more semiconductor processing tools may be used to deposit material of an interconnect structure (e.g., a source/drain interconnect structure 138, a gate interconnect structure 140, a merged interconnect structure 142) over the top surface of the conductive structure in the recess, as described herein. In some implementations, a bottom surface (e.g., a bottom surface 310, a bottom surface 710, a bottom surface 820, a bottom surface 822) of the interconnect structure is convex and conforms to the top surface of the conductive structure.

Process 900 may include additional implementations, such as any single implementation or any combination of implementations described below and/or in connection with one or more other processes described elsewhere herein.

In a first implementation, performing the second etch operation includes performing the second etch operation using an oxygen (O)-containing etchant.

In a second implementation, alone or in combination with the first implementation, the oxygen-containing etchant includes an ozone (O₃)-based etchant.

In a third implementation, alone or in combination with one or more of the first and second implementations, the ozone-based etchant includes a wet ozone-based etchant.

In a fourth implementation, alone or in combination with one or more of the first through third implementations, process 900 includes forming a liner (e.g., a liner 502, a liner 708, a liner 818) on the top surface of the conductive structure prior to forming the interconnect structure, where an interface between the interconnect structure and the ESL, and an interface between the interconnect structure and the dielectric layer, are substantially free of the liner.

In a fifth implementation, alone or in combination with one or more of the first through fourth implementations, the conductive structure includes a source/drain contact structure (e.g., a source/drain contact structure 126) of the integrated circuit device, and the interconnect structure includes a source/drain interconnect structure (e.g., a source/drain interconnect structure 138).

In a sixth implementation, alone or in combination with one or more of the first through fifth implementations, the conductive structure includes a gate structure (e.g., a gate structure 118) of the integrated circuit device, and wherein the interconnect structure includes a gate interconnect structure (e.g., a gate interconnect structure 140).

In a seventh implementation, alone or in combination with one or more of the first through sixth implementations, the conductive structure includes a source/drain contact structure (e.g., a source/drain contact structure 126) of the integrated circuit device, and the interconnect structure includes a merged interconnect structure (e.g., a merged interconnect structure 142) that is formed over the source/drain contact structure and a gate contact structure (e.g., a gate structure 118) of the integrated circuit device.

Although FIG. 9 shows example blocks of process 900, in some implementations, process 900 includes additional blocks, fewer blocks, different blocks, or differently arranged blocks than those depicted in FIG. 9. Additionally, or alternatively, two or more of the blocks of process 900 may be performed in parallel.

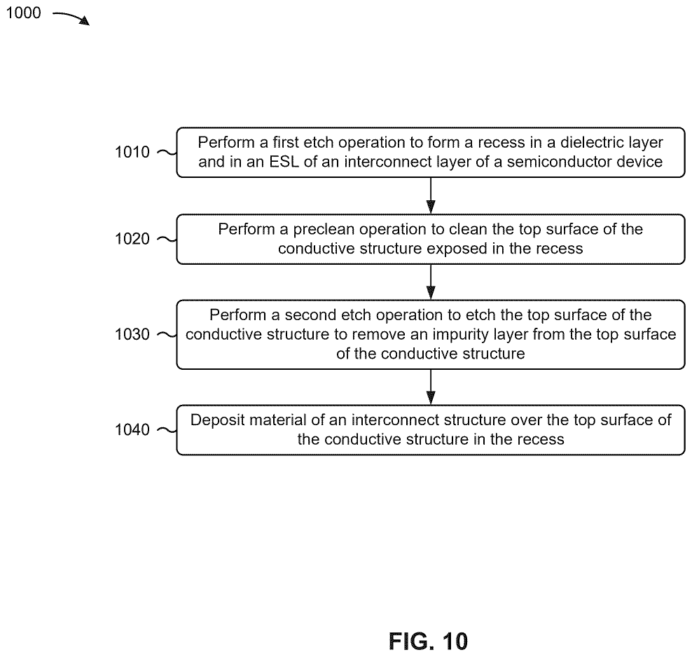

FIG. 10 is a flowchart of an example process 1000 associated with forming a semiconductor device described herein. In some implementations, one or more process blocks of FIG. 10 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 10, process 1000 may include performing a first etch operation to form a recess in a dielectric layer and in an ESL of an interconnect layer of a semiconductor device (block 1010). For example, one or more semiconductor processing tools may be used to perform a first etch operation to form a recess (e.g., a recess 302, a recess 702, a recess 802) in a dielectric layer (e.g., an ILD layer 130) and in an ESL (e.g., an ESL 132) of an interconnect layer (e.g., an interconnect layer 104) of a semiconductor device (e.g., a semiconductor device 100), as described herein. In some implementations, the dielectric layer is above the ESL. In some implementations, the ESL is above a conductive structure (e.g., a gate structure 118, a source/drain contact structure 126) of an integrated circuit device in a device layer (e.g., a device layer 102) of the semiconductor device. In some implementations, a top surface (e.g., a top surface 304, a top surface 704, a top surface 808, a top surface 810) of the conductive structure is exposed in the recess.

As further shown in FIG. 10, process 1000 may include performing a preclean operation to clean the top surface of the conductive structure exposed in the recess (block 1020). For example, one or more semiconductor processing tools may be used to perform a preclean operation to clean the top surface of the conductive structure exposed in the recess, as described herein.

As further shown in FIG. 10, process 1000 may include performing a second etch operation to etch the top surface of the conductive structure to remove an impurity layer from the top surface of the conductive structure (block 1030). For example, one or more semiconductor processing tools may be used to perform a second etch operation to etch the top surface of the conductive structure to remove an impurity layer (e.g., an impurity layer 306, an impurity layer 706, an impurity layer 814, an impurity layer 816) from the top surface of the conductive structure, as described herein. In some implementations, removal of the impurity layer results in the top surface of the conductive structure being recessed.

As further shown in FIG. 10, process 1000 may include depositing material of an interconnect structure over the top surface of the conductive structure in the recess (block 1040). For example, one or more semiconductor processing tools may be used to deposit material of an interconnect structure (e.g., a source/drain interconnect structure 138, a gate interconnect structure 140, a merged interconnect structure 142) over the top surface of the conductive structure in the recess, as described herein. In some implementations, a bottom surface (e.g., a bottom surface 310, a bottom surface 710, a bottom surface 820, a bottom surface 822) of the interconnect structure extends below the ESL and into the top surface of the conductive structure.

Process 1000 may include additional implementations, such as any single implementation or any combination of implementations described below and/or in connection with one or more other processes described elsewhere herein.

In a first implementation, performing the preclean operation includes performing the preclean operation using an isopropyl alcohol (IPA) cleaning agent, wherein performing the second etch operation includes performing the second etch operation using an ozonated water etchant.

In a second implementation, alone or in combination with the first implementation, a concentration of ozone (O₃) in the ozonated water etchant is included in a range of approximately 6 parts per million to approximately 50 parts per million.

In a third implementation, alone or in combination with one or more of the first and second implementations, the second etch operation is performed at a temperature that is included in a range of approximately 25 degrees Celsius to approximately 100 degrees Celsius.

In a fourth implementation, alone or in combination with one or more of the first through third implementations, process 1000 includes performing, after the second etch operation and prior to forming the interconnect structure, a first post-clean operation using a hot deionized water (HDI) cleaning agent.

In a fifth implementation, alone or in combination with one or more of the first through fourth implementations, process 1000 includes performing, after the first post-clean operation and prior to forming the interconnect structure, a second post-clean operation using a hydrochloric acid (HCl) chelating agent.

Although FIG. 10 shows example blocks of process 1000, in some implementations, process 1000 includes additional blocks, fewer blocks, different blocks, or differently arranged blocks than those depicted in FIG. 10. Additionally, or alternatively, two or more of the blocks of process 1000 may be performed in parallel.

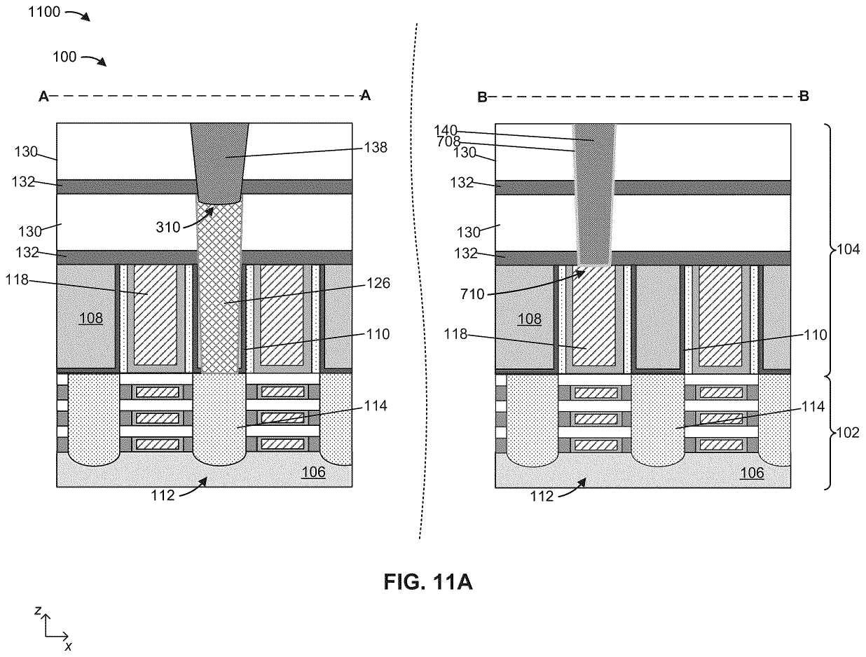

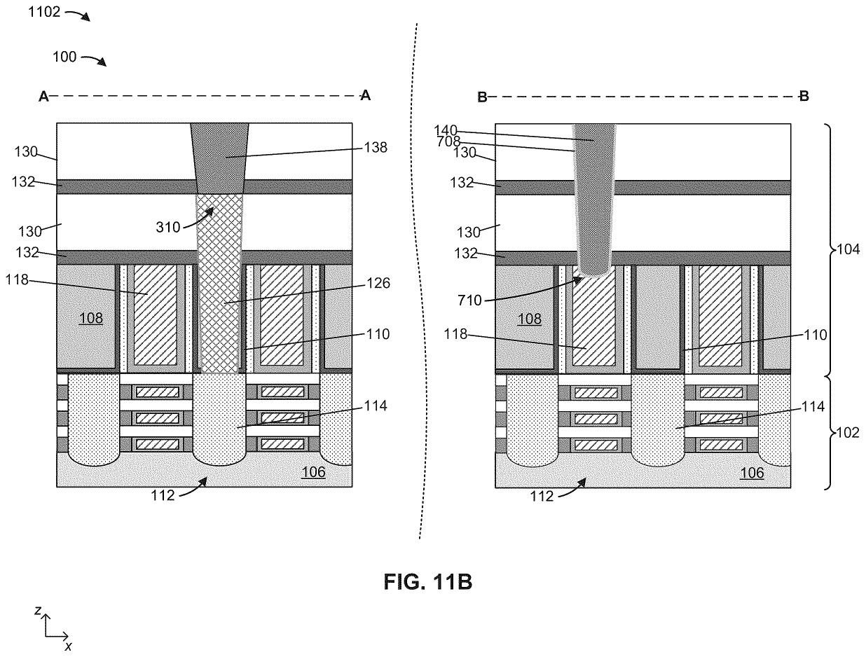

FIGS. 11A and 11B are diagrams of example implementations of the semiconductor device 100 described herein. As shown in FIG. 11A, in an example implementation 1100, the semiconductor device 100 may include a source/drain interconnect structure 138 with a convex bottom surface 310 that is recessed within a convex top surface of an underlying source/drain contact structure 126 (which may be formed according to techniques described in connection with one or more of FIGS. 3A-3G, 4A-4D, 5A-5D, and/or 6A-6C), and may include a gate contact structure 140 having a substantially flat bottom surface 710 (which may be formed by omitting the use of an etch to remove an impurity layer 706 described in connection with FIGS. 7A-7F).

As shown in FIG. 11B, in an example implementation 1102, the semiconductor device 100 may include a gate interconnect structure 140 with a convex bottom surface 710 that is recessed within a convex top surface of an underlying gate structure 118 (which may be formed according to techniques described in connection with FIGS. 7A-7F), and may include a source/drain contact structure 138 having a substantially flat bottom surface 310 (which may be formed by omitting the use of an etch to remove an impurity layer 306 described in connection with FIGS. 3A-3G, 4A-4D, 5A-5D, and/or 6A-6C).

As indicated above, FIGS. 11A and 11B are provided as examples. Other examples may differ from what is described with regard to FIGS. 11A and 11B.

In this way, a first etch operation is performed to form a recess for an interconnect structure in an interconnect layer of a semiconductor device over a contact structure and/or a gate structure of an integrated circuit device in a device layer of the semiconductor device.

Contaminants such as native oxides and/or impurities may become embedded in the exposed surfaces of the contact structure and/or the gate structure in the recess prior to formation of the interconnect structure in the recess. To remove these contaminants, a second etch operation may be performed prior to formation of the interconnect structure to etch the exposed surfaces of the contact structure and/or the gate structure in the recess. The second etch operation may be performed using a mild etchant, such as ozonated deionized water, to remove a small amount of material from the exposed surfaces of the contact structure and/or the gate structure and to avoid excessive etching of the exposed surfaces of the contact structure and/or the gate structure. As a result of the second etch operation, the exposed surfaces of the contact structure and/or the gate structure in the recess may be concave or recessed. The material of the interconnect structure may then be deposited in the recess such that the interface between the interconnect structure and the contact structure and/or the gate structure is substantially free of the contaminants. In this way, a low contact resistance may be achieved at the interface, which may enable the semiconductor device to achieve greater power efficiency and faster operating speeds.

As described in greater detail above, some implementations described herein provide a method. The method includes performing a first etch operation to form a recess in a dielectric layer and in an ESL of an interconnect layer of a semiconductor device, where the dielectric layer is above the ESL, where the ESL is above a conductive structure of an integrated circuit device in a device layer of the semiconductor device, and where a top surface of the conductive structure is exposed in the recess. The method includes performing a second etch operation to etch the top surface of the conductive structure such that the top surface of the conductive structure is concave. The method includes depositing material of an interconnect structure over the top surface of the conductive structure in the recess, where a bottom surface of the interconnect structure is convex and conforms to the top surface of the conductive structure.

As described in greater detail above, some implementations described herein provide a method. The method includes performing a first etch operation to form a recess in a dielectric layer and in an ESL of an interconnect layer of a semiconductor device, where the dielectric layer is above the ESL, where the ESL is above a conductive structure of an integrated circuit device in a device layer of the semiconductor device, and where a top surface of the conductive structure is exposed in the recess. The method includes performing a preclean operation to clean the top surface of the conductive structure exposed in the recess. The method includes performing a second etch operation to etch the top surface of the conductive structure to remove an impurity layer from the top surface of the conductive structure, where removal of the impurity layer results in the top surface of the conductive structure being recessed. The method includes depositing material of an interconnect structure over the top surface of the conductive structure in the recess, where a bottom surface of the interconnect structure extends below the ESL and into the top surface of the conductive structure.

As described in greater detail above, some implementations described herein provide a semiconductor device. The semiconductor device includes a device layer. The semiconductor device includes an integrated circuit device in the device layer. The semiconductor device includes an interconnect layer over the integrated circuit device. The interconnect layer includes a plurality of ILD layers and a plurality of ESLs interleaving the plurality of ILD layers. The interconnect layer includes a plurality of metallization structures in the plurality of ILD layers and a plurality of interconnect structures. A first interconnect structure of the plurality of interconnect structures extends vertically through a first ESL of the plurality of ESLs and a first ILD layer of the plurality of ILD layers to couple two or more of the plurality of metallization structures. A second interconnect structure extends vertically through a second ESL of the plurality of ESLs and a second ILD layer of the plurality of ILD layers to couple the integrated circuit device to the interconnect layer. A first dielectric constant of the second ESL is greater than a second dielectric constant of the second ILD layer. A bottom surface of the second interconnect structure is below the second ESL and is recessed in a top surface of a conductive structure of the integrated circuit device. An interface between the bottom surface of the second interconnect structure and the top surface of the conductive structure is free of a nitride of a metal of the conductive structure.

The terms “approximately” and “substantially” can indicate a value of a given quantity that varies within 5% of the value (e.g., ±1%, ±2%, ±3%, +4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
performing a first etch operation to form a recess in a dielectric layer and in an etch stop layer (ESL) of an interconnect layer of a semiconductor device,
wherein the dielectric layer is above the ESL,
wherein the ESL is above a conductive structure of an integrated circuit device in a device layer of the semiconductor device, and
wherein a top surface of the conductive structure is exposed in the recess;
performing a second etch operation by applying an oxidizing agent to etch the top surface of the conductive structure such that the top surface of the conductive structure is concave; and
depositing material of an interconnect structure over the top surface of the conductive structure in the recess,
wherein a bottom surface of the interconnect structure is convex and conforms to the top surface of the conductive structure.

2. The method of claim 1, wherein the oxidizing agent contains oxygen (O).

3. The method of claim 2, wherein the oxidizing agent comprises ozone (O₃).

4. The method of claim 3, wherein the oxidizing agent comprises a wet ozone-based etchant.

5. The method of claim 1, further comprising:
forming a liner on the top surface of the conductive structure prior to forming the interconnect structure,
wherein an interface between the interconnect structure and the ESL, and an interface between the interconnect structure and the dielectric layer, are substantially free of the liner.

6. The method of claim 1, wherein the conductive structure comprises a source/drain contact structure of the integrated circuit device; and
wherein the interconnect structure comprises a source/drain interconnect structure.

7. The method of claim 1, wherein a ratio of a depth to which the bottom surface of the interconnect structure is recessed in the conductive structure, and a lateral width of the bottom surface of the interconnect structure, is included in a range of approximately 0.5:1 to approximately 1:1.

8. The method of claim 1, wherein the conductive structure comprises a source/drain contact structure of the integrated circuit device; and
wherein the interconnect structure comprises a merged interconnect structure that is formed over the source/drain contact structure and a gate contact structure of the integrated circuit device.

9. A method, comprising:
performing a first etch operation to form a recess in a dielectric layer and in an etch stop layer (ESL) of an interconnect layer of a semiconductor device,
wherein the dielectric layer is above the ESL,
wherein the ESL is above a conductive structure of an integrated circuit device in a device layer of the semiconductor device, and
wherein a top surface of the conductive structure is exposed in the recess;
performing a second etch operation to etch the top surface of the conductive structure to remove an impurity layer from the top surface of the conductive structure,
wherein removal of the impurity layer results in the top surface of the conductive structure being recessed; and
depositing material of an interconnect structure over the top surface of the conductive structure in the recess,
wherein a bottom surface of the interconnect structure extends below the ESL and into the top surface of the conductive structure.

10. The method of claim 9, further comprising:
performing a preclean operation using an isopropyl alcohol (IPA) cleaning agent,
wherein performing the second etch operation comprises:
performing the second etch operation using an ozonated water etchant.

11. The method of claim 10, wherein a concentration of ozone (O₃) in the ozonated water etchant is included in a range of approximately 6 parts per million to approximately 50 parts per million.

12. The method of claim 9, wherein the second etch operation is performed at a temperature that is included in a range of approximately 25 degrees Celsius to approximately 100 degrees Celsius.

13. The method of claim 9, wherein a ratio of a depth to which the bottom surface of the interconnect structure extends below the ESL, and a lateral width of the bottom surface of the interconnect structure, is included in a range of approximately 0.5:1 to approximately 1:1.

14. The method of claim 13, further comprising:
performing, after the first post-clean operation and prior to forming the interconnect structure, a second post-clean operation using a hydrochloric acid (HCl) chelating agent.

15. A semiconductor device, comprising:
a device layer;
an integrated circuit device in the device layer; and
an interconnect layer, over the integrated circuit device, comprising:
a plurality of interlayer dielectric (ILD) layers;
a plurality of etch stop layers (ESLs) interleaving the plurality of ILD layers;
a plurality of metallization structures in the plurality of ILD layers; and
a plurality of interconnect structures,
wherein a first interconnect structure of the plurality of interconnect structures extends vertically through a first ESL of the plurality of ESLs and a first ILD layer of the plurality of ILD layers to couple two or more of the plurality of metallization structures,
wherein a second interconnect structure extends vertically through a second ESL of the plurality of ESLs and a second ILD layer of the plurality of ILD layers to couple the integrated circuit device to the interconnect layer,
wherein a first dielectric constant of the second ESL is greater than a second dielectric constant of the second ILD layer,
wherein a bottom surface of the second interconnect structure is below the second ESL and is recessed in a top surface of a conductive structure of the integrated circuit device, and
wherein a ratio of a depth to which the bottom surface of the interconnect structure is recessed in the top surface of the conductive structure, and a lateral width of the bottom surface of the interconnect structure, is included in a range of approximately 0.5:1 to approximately 1:1.

16. The semiconductor device of claim 15, wherein the interface between the bottom surface of the second interconnect structure and the top surface of the conductive structure is non-linear.

17. The semiconductor device of claim 15, wherein the interface between the bottom surface of the second interconnect structure and the top surface of the conductive structure is curved upward from a center of the second interconnect structure to a perimeter of the second interconnect structure.

18. The semiconductor device of claim 15, further comprising:
a liner between the bottom surface of the second interconnect structure and the top surface of the conductive structure,
wherein the liner is located below the second ESL.

19. The semiconductor device of claim 15, wherein the conductive structure comprises a source/drain contact structure of the integrated circuit device, and
wherein the second interconnect structure comprises a source/drain interconnect structure.

20. The semiconductor device of claim 15, wherein the conductive structure comprises a gate structure of the integrated circuit device, and
wherein the second interconnect structure comprises a gate interconnect structure.
